(19) United States
(12) Patent Application Publication
(10) Pub. No.: US 2012/0000415 A1
(43) Pub. Date: Jan. 5, 2012

(54) Large Area Nitride Crystal and Method for Making It

(75) Inventors: Mark P. D'Evelyn, Goleta, CA (US); James S. Speck, Goleta, CA (US)

(73) Assignee: Soraa, Inc., Goleta, CA (US)

(21) Appl. No.: 13/160,307

(22) Filed: Jun. 14, 2011

Related U.S. Application Data
(60) Provisional application No. 61/356,489, filed on Jun. 18, 2010.
(60) Provisional application No. 61/386,879, filed on Sep. 27, 2010.

(51) Int. Cl. C30B 25/02; C30B 23/02

(52) U.S. Cl. 117/94; 117/106

(57) ABSTRACT

Techniques for processing materials in supercritical fluids include processing in a capsule disposed within a high-pressure apparatus enclosure. The invention is useful for growing crystals of: GaN; AN; InN; and their alloys, namely: InGaN; AlGaN; and AlInGaN; for manufacture of bulk or patterned substrates, which in turn can be used to make optoelectronic devices, lasers, light emitting diodes, solar cells, photoelectrochemical water splitting and hydrogen generation, photodetectors, integrated circuits, and transistors.

### CROSS REFERENCE TO RELATED APPLICATIONS

This application claims priority to U.S. Provisional Application No. 61/356,489, filed Jun. 18, 2010; and U.S. Provisional Application No. 61/386,879, filed Sep. 27, 2010, each of which is incorporated herein by reference for all purposes.

### BACKGROUND OF THE INVENTION

This invention relates to techniques for processing materials in supercritical fluids. Embodiments of the invention include techniques for material processing in a capsule disposed within a high-pressure apparatus enclosure. The invention can be applied to growing crystals of: GaN; AN; InN; and their alloys, namely: InGaN; AlGaN; and AlInGaN; and others for manufacture of bulk or patterned substrates. Such bulk or patterned substrates can be used for a variety of applications including optoelectronic devices, lasers, light emitting diodes, solar cells, photoelectrochemical water splitting and hydrogen generation, photodetectors, integrated circuits, and transistors, among other devices.

Large area, high quality crystals and substrates, for example, nitride crystals and substrates, are needed for a variety of applications, including light emitting diodes, laser diodes, transistors, and photodetectors. In general, there is an economy of scale with device processing, so that the cost per device is reduced as the diameter of the substrate is increased. In addition, large area seed crystals are needed for bulk nitride crystal growth.

There are known methods for fabrication of large area gallium nitride (GaN) crystals with a (0 0 0 1) c-plane orientation. In many cases, hydride vapor phase epitaxy (HVPE) is used to deposit thick layers of gallium nitride on a non-gallium-nitride substrate such as sapphire, followed by the removal of the substrate. These methods have demonstrated capability for producing free-standing c-plane GaN wafers 50-75 millimeters in diameter, and 100 millimeter diameters are expected. The typical average dislocation density, however, in these crystals, about 10⁶-10⁸ cm⁻², is undesirably high for many applications. Techniques have been developed to gather the dislocations into bundles or low-angle grain boundaries, but it is still very difficult to produce dislocation densities below 10⁴ cm⁻² in a large area single grain by these methods, and the relatively high concentration of high-dislocation-density bundles or grain boundaries creates difficulties, performance degradation, and/or yield losses for the device manufacturer.

The non-polar planes of gallium nitride, such as {1 0-1 0} and {1 1-2 0}, and the semi-polar planes of gallium nitride, such as {1 0-1±1}, {1 0-1±2}, {1 0-1±3}, and {1 1-2±2}, {2 0-2 1} are attractive for a number of applications. Unfortunately, no large area, high quality non-polar or semi-polar GaN wafers are generally available for large scale commercial applications. Other conventional methods for growing very high quality GaN crystals, for example, with a dislocation density less than 10⁴ cm⁻² have been proposed. These crystals, however, are typically small, less than 1-5 centimeters in diameter, and are not commercially available.

Dwilinski, et al. [U.S. Patent Application No. 2008/0156254] suggested a method for merging elementary GaN seed crystals into a larger compound crystal by a tiling method. The method uses elementary GaN seed crystals grown by hydride vapor phase epitaxy (HVPE) and polishing the edges of the elementary crystals at oblique angles to cause merger in fast-growing directions. Dwilinski, et al., however, has limitations. Dwilinski, et al. did not specify the accuracy of the crystallographic orientation between the merged elementary seed crystals nor provide a method capable of providing highly accurate crystallographic registry between the elementary seed crystals, and observed defects resulting from the merging of the elementary seed crystals.

Conventional techniques are inadequate for failing to meaningfully increase the available size of high-quality nitride crystals while maintaining extremely accurate crystallographic orientation across the crystals.

### BRIEF SUMMARY OF THE INVENTION

This invention provides a method for growth of a large-area, gallium-containing nitride crystal. The method includes providing at least two nitride crystals having a dislocation density below about 10⁷ cm⁻² together with a handle substrate. The nitride crystals are bonded to the handle substrate. Then the nitride crystals are grown to coalescence into a merged nitride crystal. The polar misorientation angle γ between the first nitride crystal and the second nitride crystal is less than 0.5 degree and azimuthal misorientation angles α and β are less than 1 degree. A semiconductor structure can be formed on the nitride crystals as desired.

In another embodiment, the invention includes the steps above, but also includes providing a release layer and a high quality epitaxial layer on each of the two nitride crystals. The epitaxial layers are grown to cause coalescence into a merged nitride crystal. The polar misorientation angle γ between the first nitride crystal and the second nitride crystal is less than 0.5 degree and azimuthal misorientation angles α and β are less than 1 degree.

The invention can provide a crystal that includes at least two single crystal domains having a nitride composition and a dislocation density within the domain less than 10⁷ cm⁻². The two single crystal domains are separated by a line of dislocations with a linear density less than 50 cm⁻¹ and preferably less than 5×10⁵ cm⁻¹. The polar misorientation angle γ between the first domain and the second domain is less than 0.5 degree and the azimuthal misorientation angles α and β are less than 1 degree.

### BRIEF DESCRIPTION OF THE DRAWINGS

FIGS. 1a, 1b, 1c, 1d, 1e, 1f, 1g, 1h, 1i, 1j, and 1k are diagrams illustrating a method for wafer bonding of crystals;

FIG. 2 is a diagram illustrating the crystallographic misorientation between two adjacent wafer-bonded crystals;

FIG. 3 is a diagram illustrating arrangements of tiled crystals;

FIGS. 4a, 4b, 5, and 6 are diagrams illustrating a method for coalescence of wafer-bonded crystals;

FIG. 7 is a diagram illustrating a merged crystal; and

FIGS. 8, 9, and 10 are diagrams illustrating lateral growth from a seed crystal.

### DETAILED DESCRIPTION OF THE INVENTION

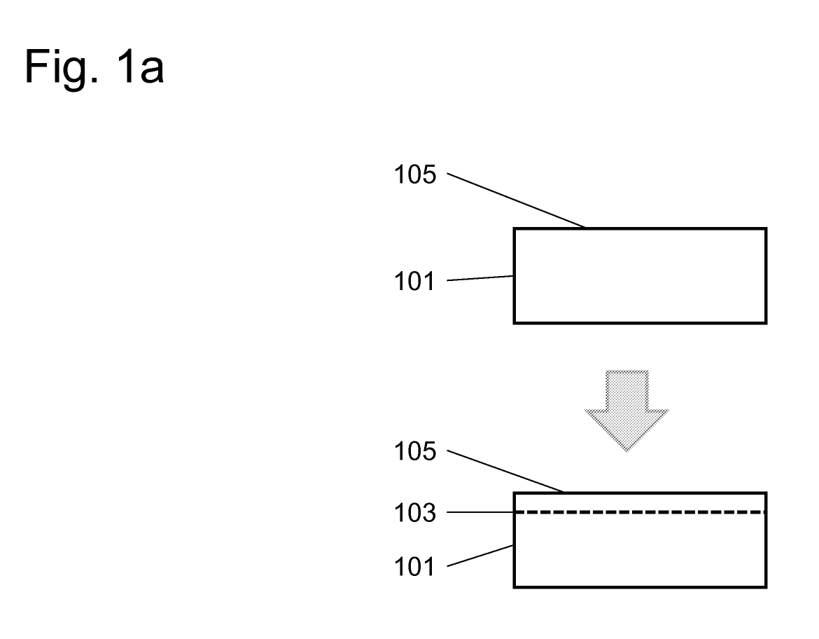

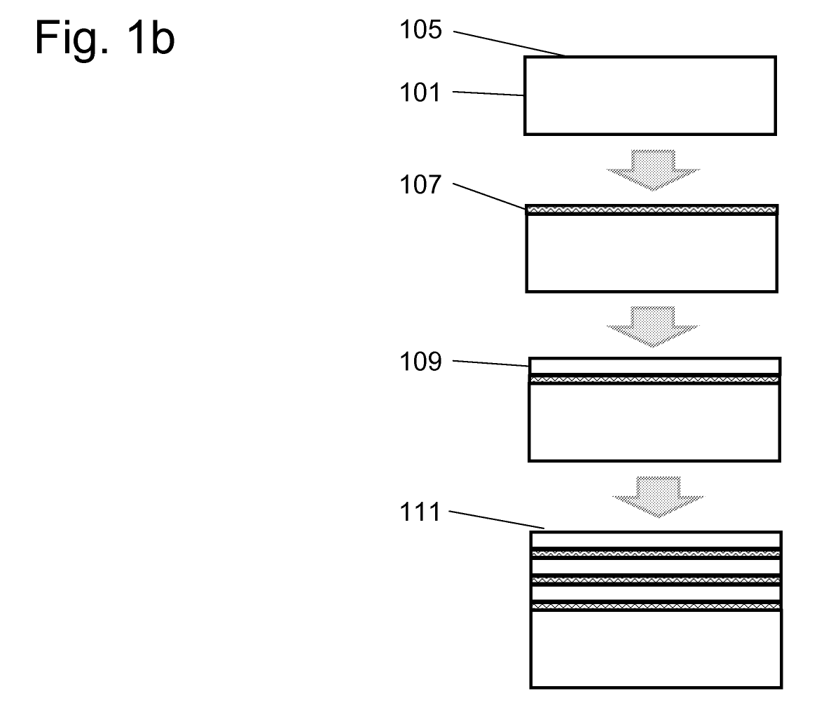

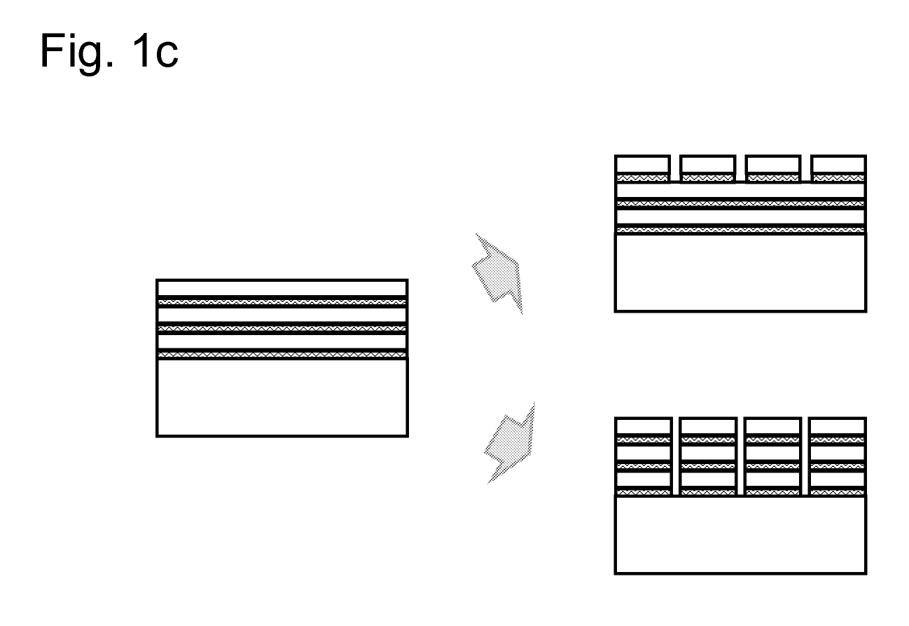

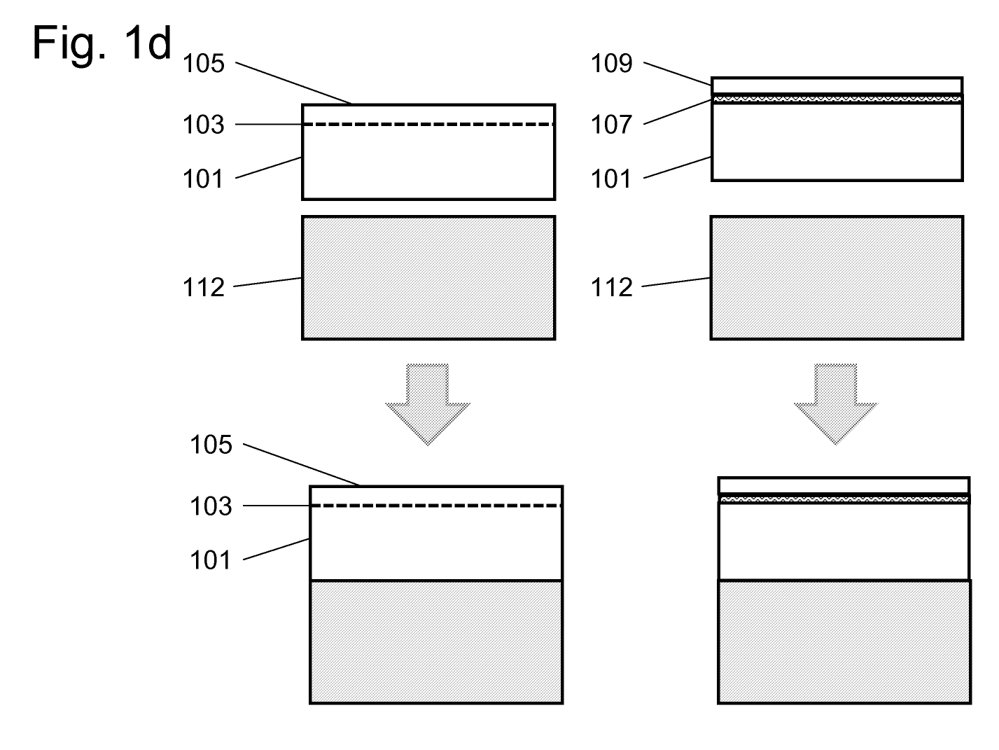

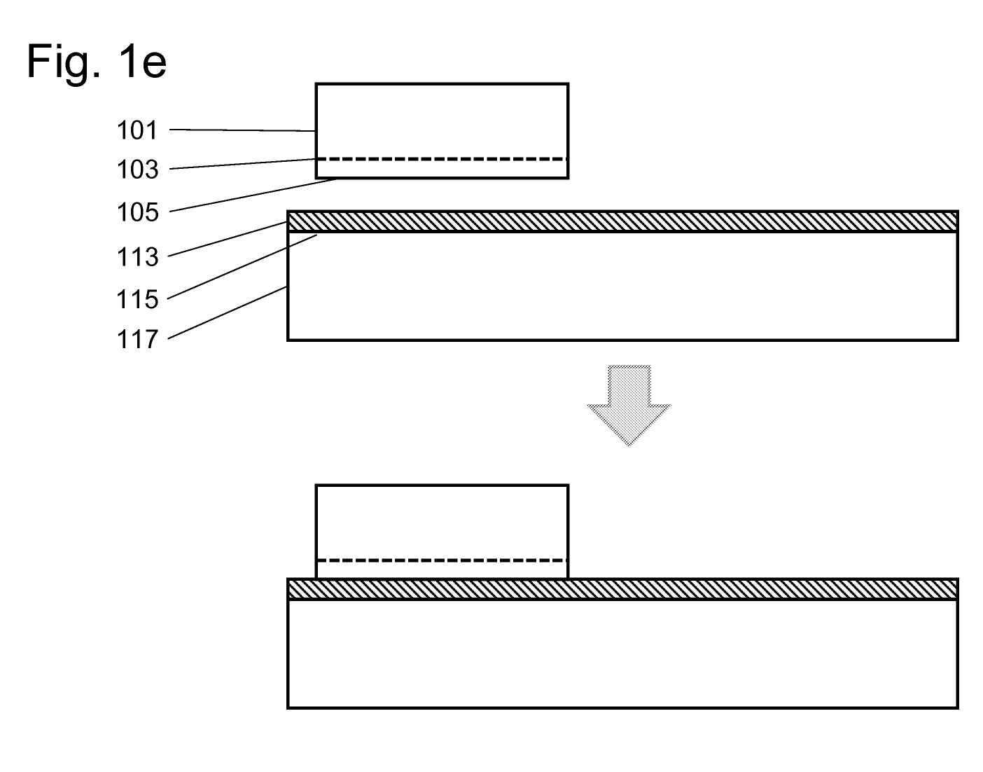

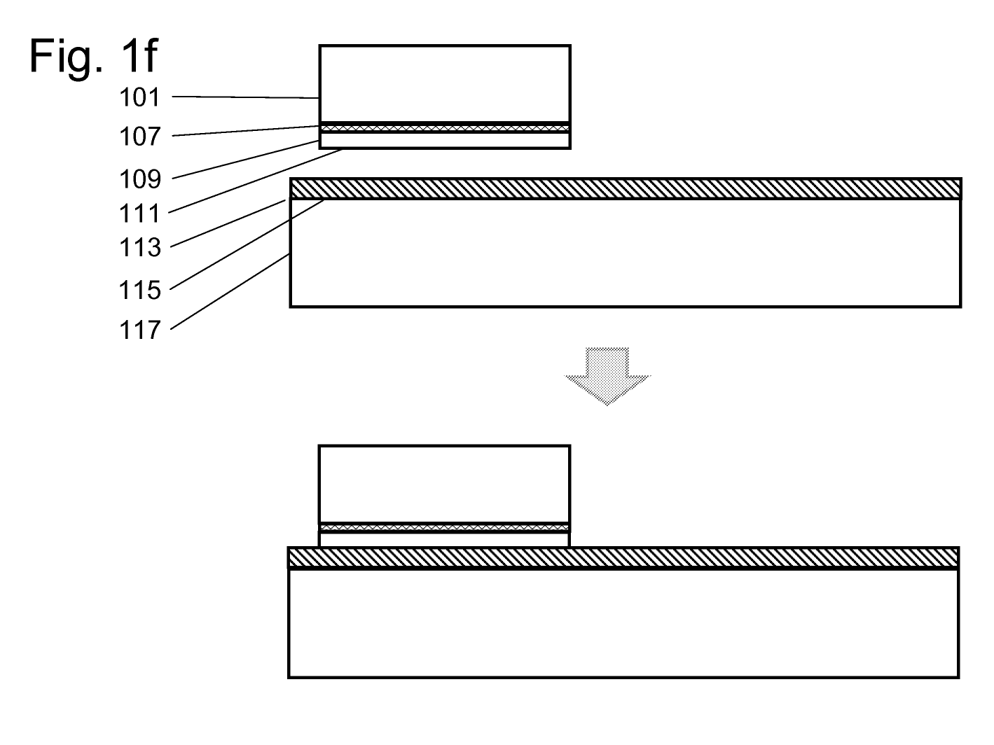

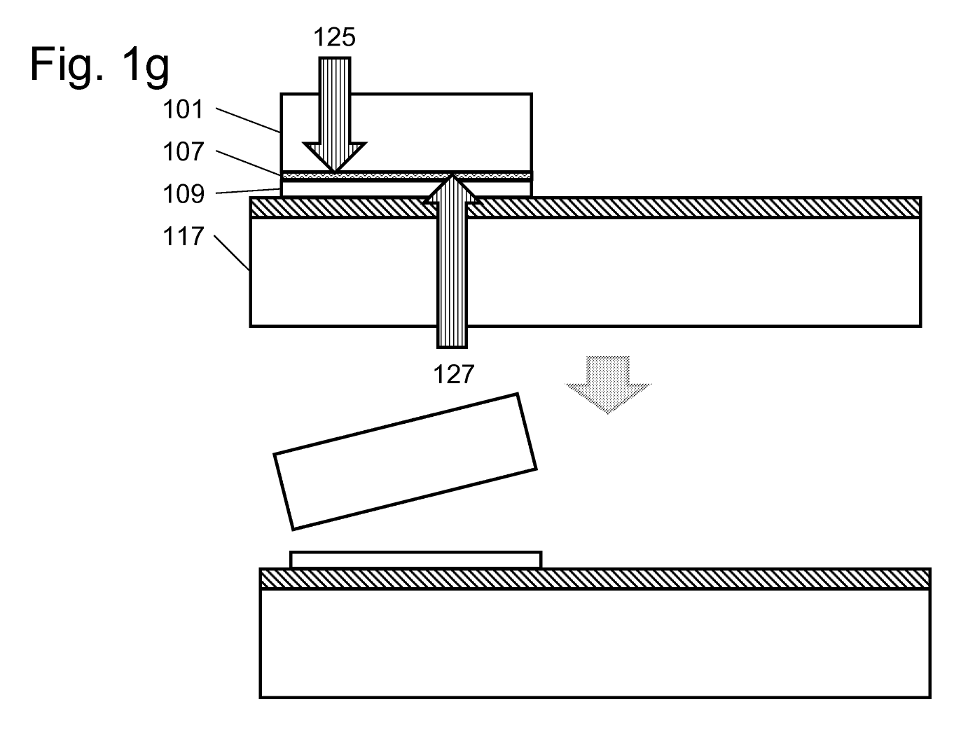

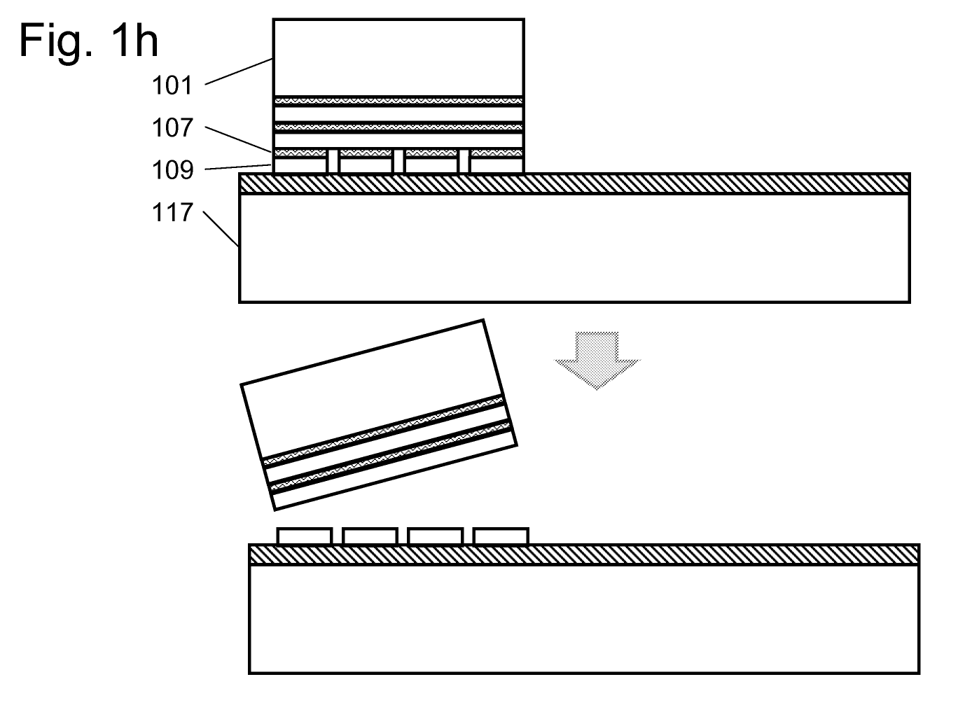

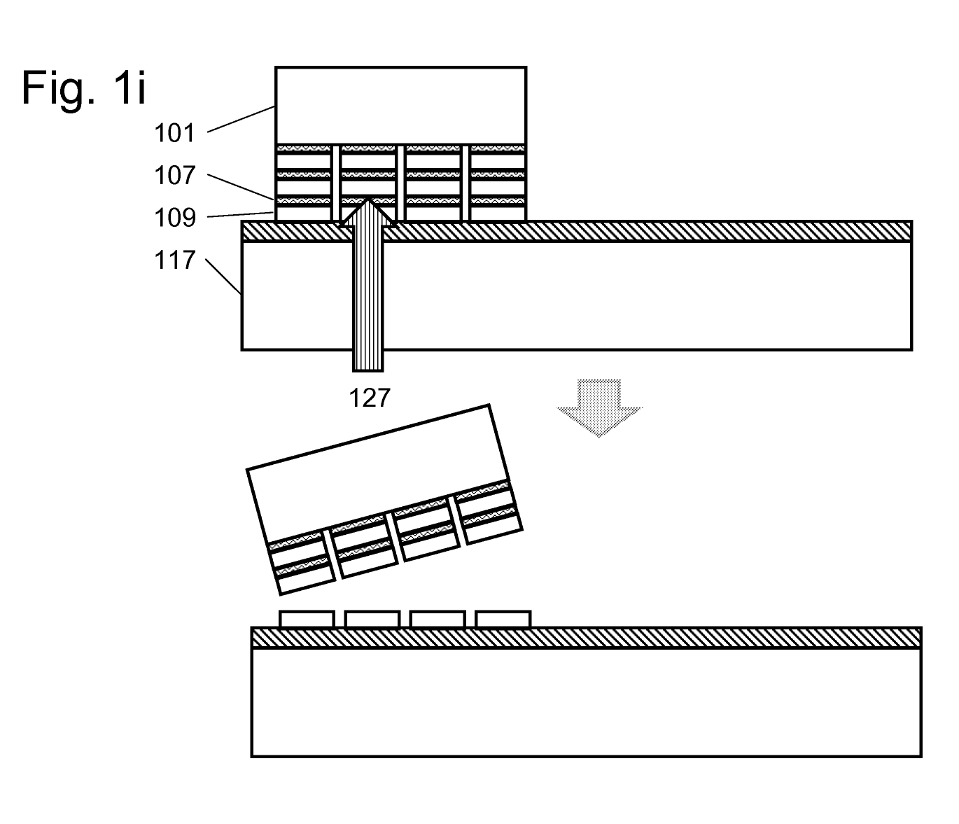

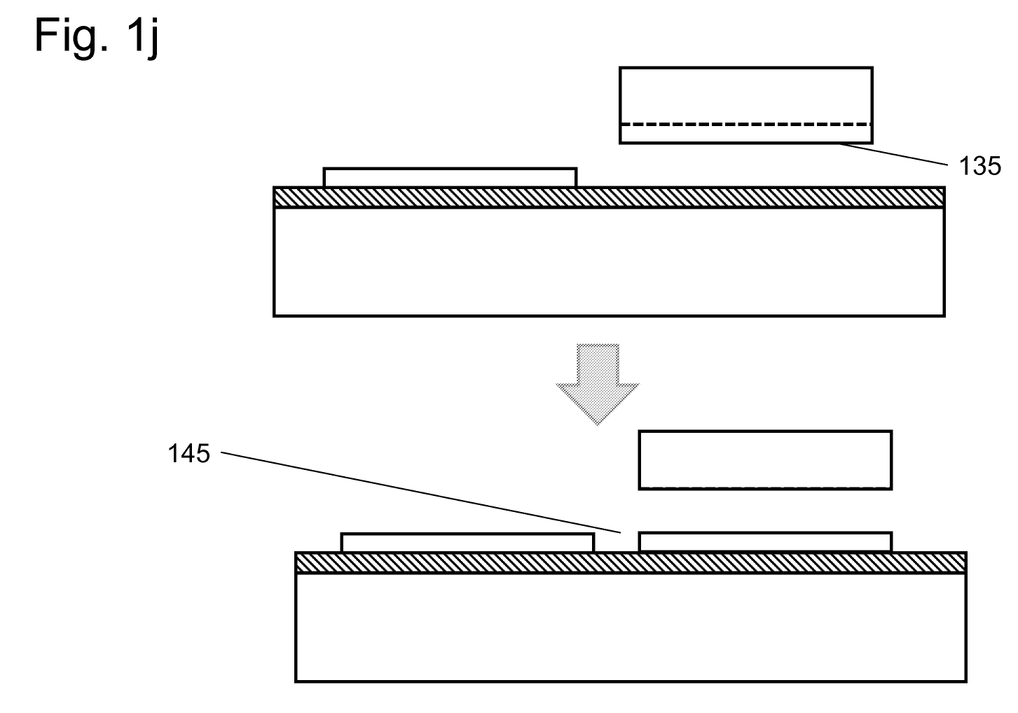

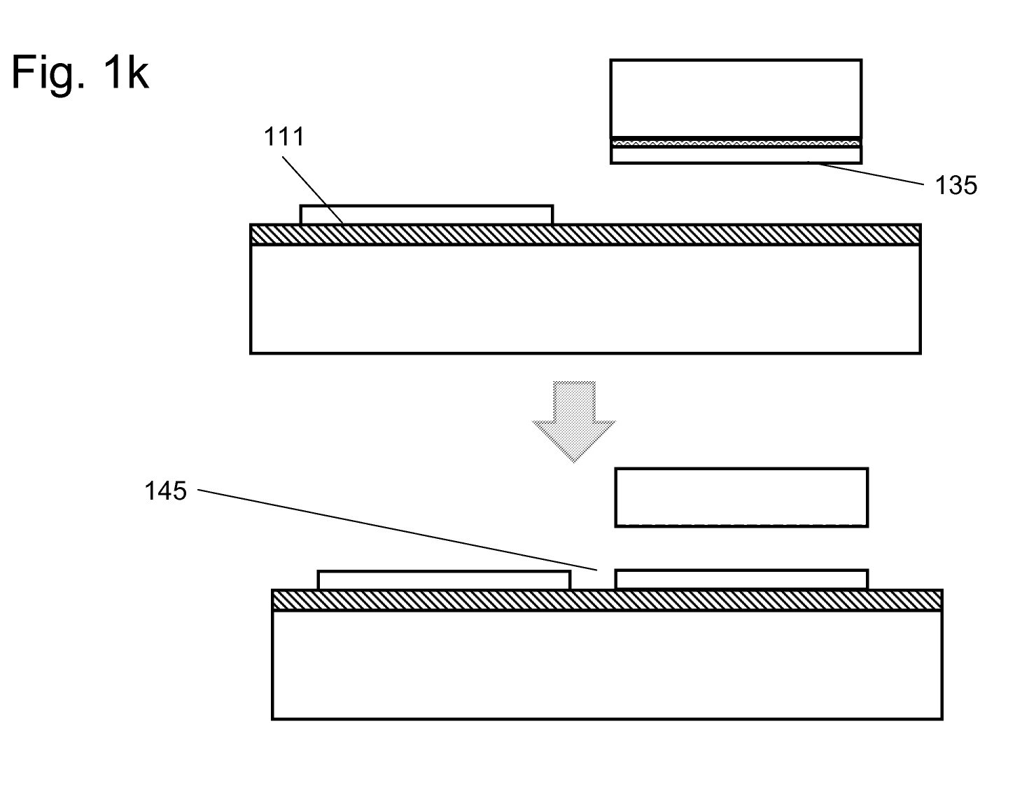

Referring to FIG. 1a, a crystal 101 having a first surface 105 is provided. We will often refer to crystal 101 as a “nitride crystal”, as nitride crystals with a wurtzite crystal structure comprise a preferred embodiment. The method disclosed, however, has broader generality, and the term “nitride crystal” should be understood to include non-nitride crystals as well as nitride crystals. Examples of non-nitride crystals for which this invention may be applicable include diamond, cubic boron nitride, boron carbide, silicon, germanium, silicon germanium, indium phosphide, gallium phosphide, zinc oxide, zinc selenide, gallium arsenide, cadmium telluride, and cadmium zinc telluride. In preferred embodiments, nitride crystal 101 comprises GaN or AlₓIn_{y}Ga(_{1-x-y})N, where 0≦x, y≦1 and has a very high crystallographic quality. In another embodiment, crystal 101 has a wurtzite crystal structure and is ZnO, ZnS, AgI, CdS, CdSe, 2H-SiC, 4H-SiC, and 6H-SiC. Nitride crystal 101 preferably has a surface dislocation density less than about 10⁷ cm⁻², 10⁶ cm⁻², 10⁵ cm⁻², 10⁴ cm⁻², 10³ cm⁻², or even less than about 10² cm⁻². Nitride crystal 101 also preferably has a stacking-fault concentration below 10³ cm⁻¹, 10² cm⁻¹, 10 cm⁻¹ or even below 1 cm⁻¹. Nitride crystal 101 also has a symmetric x-ray rocking curve full width at half maximum (FWHM) less than about 300 arc sec, 200 arc sec, 100 arc sec, 50 arc sec, 35 arc sec, 25 arc sec, or even less than about 15 arc sec. Nitride crystal 101 has a crystallographic radius of curvature greater than 0.1 meter, 1 meter, 10 meters, 100 meters, or even greater than 1000 meters, in up to three independent or orthogonal directions.

Nitride crystal 101 has regions having a relatively high concentration of threading dislocations separated by regions having a relatively low concentration of threading dislocations. The concentration of threading dislocations in the relatively high concentration regions may be greater than about 10⁶ cm⁻², 10⁷ cm⁻², or even greater than about 10⁸ cm⁻². The concentration of threading dislocations in the relatively low concentration regions may be less than about 10⁶ cm⁻², 10⁵ cm⁻², or even less than about 10⁴ cm⁻². The thickness of nitride crystal 101 is between about 100 microns and about 100 millimeters, or even between about 1 millimeter and about 10 millimeters. The diameter of the crystal 101 is at least about 0.5 millimeter, 1 millimeter, 2 millimeters, 5 millimeters, 10 millimeters, 15 millimeters, 20 millimeters, 25 millimeters, 35 millimeters, 50 millimeters, 75 millimeters, 100 millimeters, 150 millimeters, and can be at least about 200 millimeters. Surface 105 has a crystallographic orientation within 5 degrees, 2 degrees, 1 degree, 0.5 degree, 0.2 degree, 0.1 degree, 0.05 degree, 0.02 degree, or even within 0.01 degree of (0 0 0 1) Ga-polar, (0 0 0 −1) N-polar, {1 0-1 0} non-polar, or {1 1-2 0} non-polar a-plane. Surface 105 may have a (h k i l) semi-polar orientation, where i=−(h+k) and l and at least one of h and k are nonzero.

In a specific embodiment, the crystallographic orientation of surface 105 is within 5 degrees, 2 degrees, 1 degree, 0.5 degree, 0.2 degree, 0.1 degree, 0.05 degree, 0.02 degree, or even within 0.01 degree of {1 0-1±1}, {1 0-1±2}, {1 0-1±3},{1 1-2±2},{2 0-2±1}, {2 1-3±1}, or {3 0-3±4}. Nitride crystal 101 has a minimum lateral dimension of at least two millimeters, but it can be four millimeters, one centimeter, two centimeters, three centimeters, four centimeters, five centimeters, six centimeters, eight centimeters, or even at least ten centimeters. In another set of embodiments, crystal 101 has a cubic crystal structure. In some embodiments, crystal 101 has a cubic diamond structure and is selected from among diamond, silicon, germanium, or silicon germanium. In other embodiments, crystal 101 has a cubic zincblende structure and is selected from among cubic BN, BP, BAs, AlP, AlAs, AlSb, β-SiC, GaP, GaAs, GaSb, InP, InAs, ZnS, ZnSe, CdS, CdSe, CdTe, CdZeTe, and HgCdTe. In a specific embodiment, the crystallographic orientation of surface 105 is within 5 degrees, 2 degrees, 1 degree, 0.5 degree, 0.2 degree, 0.1 degree, 0.05 degree, 0.02 degree, or even within 0.01 degree of {1 1 1}, {1 1 0}, {1 0 0}, {3 1 1}, and {2 1 1}.

In some embodiments, nitride crystal 101 is grown by hydride vapor phase epitaxy (HVPE) according to known methods. In other embodiments, nitride crystal 101 is grown by molecular beam epitaxy (MBE) or metalorganic chemical vapor deposition (MOCVD). Nitride crystal 101 may be grown on a heteroepitaxial substrate such as sapphire or gallium arsenide. In some embodiments, nitride crystal 101 is grown by a flux or high temperature solution method. In some embodiments, nitride crystal 101 is grown ammonothermally.

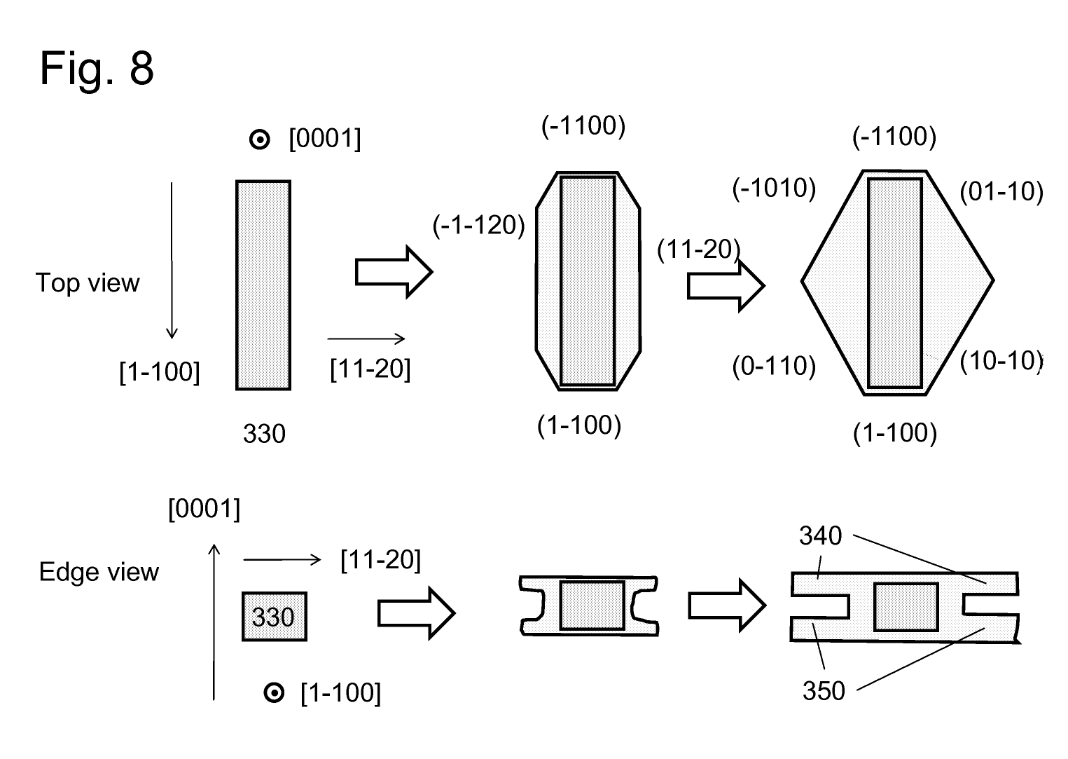

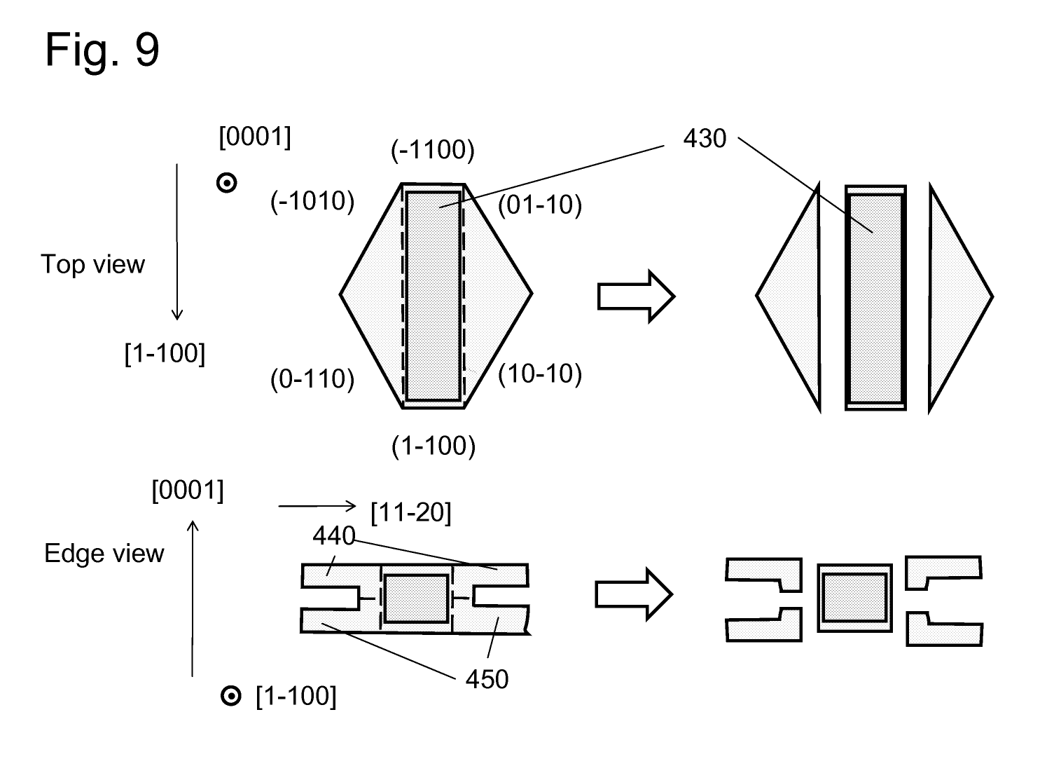

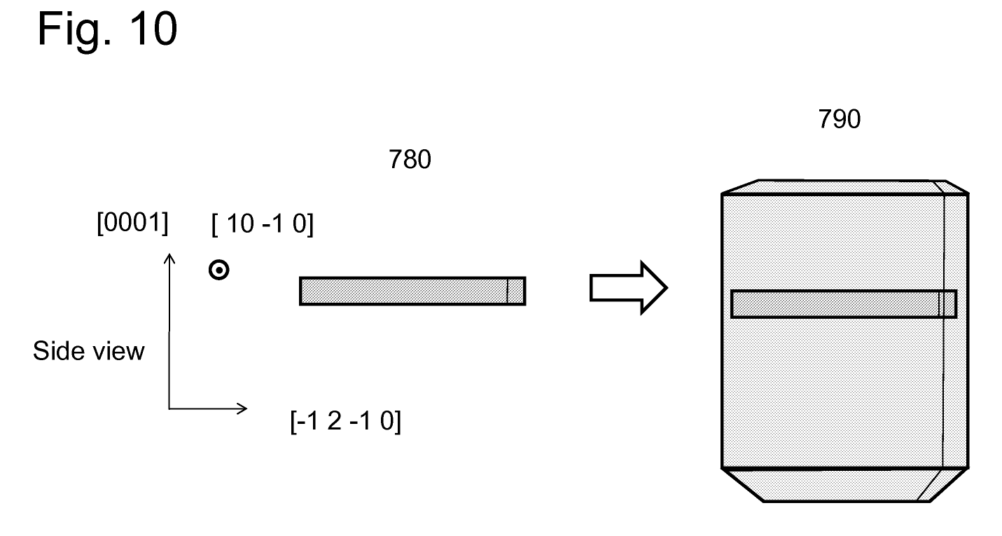

One of the steps in the preparation of nitride crystal 101 can be lateral growth from a seed crystal, as described in U.S. patent application Ser. No. 12/556,562, filed Sep. 9, 2009, and U.S. patent application Ser. No. 61/250,476, filed Oct. 9, 2009. Referring to FIG. 8, in one set of embodiments a bar-shaped seed crystal 330 having two a-plane-oriented edges is provided. Ammonothermal growth may be performed, using conditions that favor rapid growth in the a-direction, producing laterally-grown wings 340 and 350. The laterally-grown wings may be separated from the seed crystal, producing crystals with a shape approximating a half-rhombus, as shown in FIG. 9. Referring to FIG. 10, in another set of embodiments a bar-shaped seed crystal 780 having +c and −c-plane-oriented edges is provided. Ammonothermal growth may be performed, using conditions that favor rapid growth in the +c- and/or −c-directions, producing laterally-grown crystal 790. If desired, the laterally-grown wings may be separated.

Referring again to FIG. 1a, in some embodiments, the conditions for the final growth step for crystal 101 are chosen so that the crystal grows to the nominal orientation and is highly flat. For example, the growth condition may be chosen so that the growth rates in directions parallel to surface 105 are larger, by at least a factor of 5, a factor of 10, a factor of 20, or a factor of 50, than the growth rate perpendicular to surface 105. Establishment of an on-axis orientation by direct growth may be particularly advantageous when surface 105 has an orientation selected from (0 0 0 1) Ga-polar, (0 0 0 −1) N-polar, {1 0-1 0} non-polar, or {10-1±1} semi-polar. Additional steps in the preparation of nitride crystal 101 and of surface 105 may include sawing, lapping, polishing, dry etching, and chemical mechanical polishing. Surface 105 may be optically flat, with a deviation from flatness less than 1 micron, 0.5 micron, 0.2 micron, 0.1 micron, or even less than 0.05 micron. Surface 105 may be very smooth, with a root-mean-square roughness less than 5 nanometers, 2 nanometers, 1 nanometer, 0.5 nanometer, 0.2 nanometer, 0.1 nanometer, or even less than 0.05 nanometer, measured over an area of at least 10 microns×10 microns.

In some embodiments, at least one edge, at least two edges, or at least three edges of nitride crystal 101 are as-grown. In some embodiments, at least one edge, at least two edges, or at least three edges of nitride crystal 101 are cleaved. In some embodiments, at least one edge, at least two edges, or at least three edges of nitride crystal 101 are sawed, ground, lapped, polished, and/or etched, for example, by reactive ion etching (RIE) or inductively-coupled plasma (ICP). In one specific embodiment, one or more edges of the surface of crystal 101 are defined by etching one or more trenches in a larger crystal. In some embodiments, at least one edge, at least two edges, or at least three edges of nitride crystal 101 have a {1 0-1 0} m-plane orientation. In one specific embodiment, nitride crystal 101 has a substantially hexagonal shape. In another specific embodiment, nitride crystal 101 has a substantially rhombus or half-rhombus shape. In still other embodiments, nitride crystal 101 is substantially rectangular. In one specific embodiment, nitride crystal 101 has a (0 0 0 1) +c-plane edge and a (0 0 0 −1) −c-plane edge. In another specific embodiment, nitride crystal 101 has two {1 1-2 0} edges. In yet another specific embodiment, nitride crystal 101 has two {1 0-1 0} edges. In still another specific embodiment, crystal 101 has a cubic crystal structure and at least one edge, at least two edges, or at least three edges have a { 111} orientation. In yet another, specific embodiment, crystal 101 has a cubic zincblende crystal structure and at least one edge, at least two edges, or at least three edges have a {110} orientation.

Referring again to FIG. 1a, in one set of embodiments, surface 105 of nitride crystal 101 is implanted with ions, forming an implanted/damaged region 103 according to methods that are known in the art. The ion implantation may be performed with at least one of H⁺, H₂⁺, He⁺, Ne⁺, Ar⁺, Kr⁺, Xe⁺, N⁺, or N₂⁺. The implantation energy be between about 10 keV and about 1 MeV, or preferably between about 20 keV and about 200 keV. The ion fluence or dose may be between about 10¹⁶ cm⁻² and about 10¹⁹ cm⁻², between about 10¹⁷ cm⁻² and about 10¹⁸ cm⁻², or between about 2×10¹⁷ cm⁻² and about 4×10¹⁷ cm⁻². In some embodiments, the back side of crystal 101 is also implanted with ions, forming a second implanted/damaged region (not shown), with a similar ion composition, energy, and fluence, so as to minimize bow in crystal 101, as described by O. Moutanabbir and U. Gösele, J. Electronic Mater. 39, 482 (2010), which is hereby incorporated by reference in its entirety.

Referring to FIG. 1b, in some embodiments a release layer 107 is provided. In some embodiments, release layer 107 has an optical absorption coefficient greater than 1000 cm⁻¹ at at least one wavelength where nitride crystal 101 is substantially transparent, with an optical absorption coefficient less than 50 cm⁻¹, is then deposited on nitride crystal 101. In some embodiments, the release layer has an optical absorption coefficient greater than 5000 cm⁻¹ at at least one wavelength where nitride crystal 101 is substantially transparent. In some embodiments, release layer 107 can be selectively wet etched, electrochemically etched, or photoelectrochemically etched preferentially with respect to crystal 101 or with respect to high quality epitaxial layer 109. In some embodiments, the release layer comprises AlₓIn_{y}Ga_{1-x-y}N, where 0≦x, y, x+y≦1. In some embodiments the release layer further comprises at least one impurity, to render the release layer strongly absorbing at some wavelengths. A number of dopant impurities, including H, O, C, Mn, Fe, and Co, may render an AlₓIn_{y}Ga_{1-x-y}N or GaN crystal colored. Heavy doping with cobalt, in particular, can render GaN black, that is, with a high optical absorption coefficient across the visible spectrum. In particular, the optical absorption coefficient may be greater than 5000 cm⁻¹ across the entire visible spectrum, including the range between about 465 nm and about 700 nm. The optical absorption coefficient may also be greater than 5000 cm⁻¹ between about 700 nm and about 3077 nm and at wavelengths between about 3333 nm and about 6667 nm. Incorporation of In can decrease the bandgap of GaN, leading to strong absorption at wavelengths where GaN or AlGaN are substantially transparent. However, the InGaN has inferior temperature stability and a larger lattice mismatch with respect to GaN or AlGaN than does heavily-doped GaN or AlGaN. Release layer 107 may be deposited epitaxially on nitride crystal 101 by metalorganic chemical vapor deposition (MOCVD), hydride vapor phase epitaxy (HVPE), molecular beam epitaxy (MBE), ammonothermal growth, or flux growth, as described further in U.S. patent application Ser. No. 12/546458, which is hereby incorporated by reference in its entirety.

In another set of embodiments, the release layer 107 comprises nitrogen and at least one element selected from Si, Sc, Ti, V, Cr, Y, Zr, Nb, Mo, a rare earth element, Hf, Ta, and W. A metal layer may be deposited on the base crystal, to a thickness between about 1 nm and about 1 micron by sputtering, thermal evaporation, e-beam evaporation, or the like. The metal layer may then be nitrided by heating in a nitrogen-containing atmosphere such as ammonia to a temperature between about 600 degrees Celsius and about 1200 degrees Celsius. During the nitridation process the metal partially de-wets from the base crystal, creating nano-to-micro openings through which high quality epitaxy can take place. The nitridation step may be performed in an MOCVD reactor, in an HVPE reactor, or in an ammonothermal reactor immediately prior to deposition of a high quality epitaxial layer.

In still another set of embodiments, the release layer 107 comprises AlₓIn_{y}Ga_{1-x-y}N, where 0≦x, y, x+y≦1, but may not have an optical absorption coefficient larger than that of nitride crystal 101. In a preferred embodiment, nitride crystal 101 comprises GaN and release layer 107 comprises Al₁₋ₓInₓN, where x is approximately equal to 0.17 so that the release layer is lattice-matched to nitride crystal 101, also known as the nitride base crystal. Referring again to FIG. 1b, a high quality epitaxial layer 109 may be provided. In some embodiments, the high quality epitaxial layer is grown in a separate step, by MOCVD, by MBE, or by HVPE, after deposition of the release layer. In another embodiment, the high quality epitaxial layer is grown ammonothermally. The high quality epitaxial layer may have a thickness between about 0.05 micron and about 500 microns. In some embodiments the thickness of the high quality epitaxial layer is between about one micron and about 50 microns.

The high quality epitaxial layer 109 has the same crystallographic orientation as nitride crystal 101, to within about 0.5 degree, within 0.2 degree, within 0.1 degree, within 0.05 degree, within 0.02 degree, or within 0.01 degree, and very similar crystallographic properties. High quality epitaxial layer 109 may be between 0.1 micron and 50 microns thick, comprises nitrogen and may have a surface dislocation density below 10⁷ cm⁻². In preferred embodiments, high quality epitaxial layer 109 comprises GaN or AlₓIn_{y}Ga(_{1-x-y})N, where 0≦x, y≦1 and has a very high crystallographic quality. High quality epitaxial layer 109 may have a surface dislocation density less than about 10⁷ cm⁻², less than about 10⁶ cm⁻², less than about 10⁵ cm⁻², less than about 10⁴ cm⁻², less than about 10³ cm⁻², or less than about 10² cm⁻². High quality epitaxial layer 109 may have a stacking-fault concentration below 10³ cm⁻¹, below 10² cm⁻¹, below 10 cm⁻¹ or below 1 cm⁻¹. High quality epitaxial layer 109 may have a symmetric x-ray rocking curve full width at half maximum (FWHM) less than about 300 arc sec, less than about 200 arc sec, less than about 100 arc sec, less than about 50 arc sec, less than about 35 arc sec, less than about 25 arc sec, or less than about 15 arc sec. In some embodiments, the high quality epitaxial layer is substantially transparent, with an optical absorption coefficient below 100 cm⁻¹, below 50 cm⁻¹, below 5 cm⁻¹, or below 1 cm⁻¹ at wavelengths between about 700 nm and about 3077 nm and at wavelengths between about 3333 nm and about 6667 nm. In some embodiments, the high quality epitaxial layer is substantially free of low angle grain boundaries, or tilt boundaries. In other embodiments, the high quality epitaxial layer comprises at least two tilt boundaries, with the separation between adjacent tilt boundaries not less than 3 mm. The high quality epitaxial layer may have impurity concentrations of O, H, C, Na, and K below 1×10¹⁷ cm⁻³, 2×10¹⁷ cm⁻³, 1×10¹⁷ cm⁻³, 1×10¹⁶ cm⁻³ , and 1×10¹⁶ cm⁻³, respectively, as quantified by calibrated secondary ion mass spectrometry (SIMS), glow discharge mass spectrometry (GDMS), interstitial gas analysis (IGA), or the like.

Referring again to FIG. 1b, the process of depositing a release layer and a high quality epitaxial layer may be repeated at least one, at least two, at least four, at least eight, or at least sixteen times. In one set of embodiments the high quality epitaxial layers comprise GaN and the release layers comprise lattice-matched Al_{0.83}In_{0.17}N. In another set of embodiments the roles are reversed, and the release layers comprise GaN and the high quality epitaxial layers comprise lattice-matched Al_{0.83}In_{0.17}N. The outermost surface 111 of the one or more high quality epitaxial layers has the same crystallographic orientation as surface 105.

Referring to FIG. 1c, in some embodiments a series of channels are provided through a high quality epitaxial layer. A pattern, for example, a series of stripes, may be defined by conventional photolithography. Channels may be etched by reactive ion etching (RIE), inductively-coupled plasma (ICP) etching, or the like. In some embodiments the channels are etched through only a single high quality epitaxial layer. The channel may or may not cut through the outermost release layer, but the release layer is exposed in each channel. In other embodiments the channels are cut through two or more high quality epitaxial layers. The spacing between adjacent channels may be between about 10 microns and about 10 millimeters, or between about 0.1 millimeter and 1 millimeter.

Referring to FIG. 1d, in some embodiments nitride crystal 101 is affixed to block 112. Block 112 may comprise stainless steel, steel, an iron-based alloy, a nickel-based alloy, a cobalt-based alloy, a copper-based alloy, or the like. Block 112 may have edges that are machined or ground very accurately. For example, at least two parallel faces on block 112 may be parallel to within 1 degree, within 0.5 degree, within 0.2 degree, within 0.1 degree, within 0.05 degree, within 0.02 degree, or within 0.01 degree. At least two perpendicular faces on block 112 may be perpendicular to within 1 degree, within 0.5 degree, within 0.2 degree, within 0.1 degree, within 0.05 degree, within 0.02 degree, or within 0.01 degree. Nitride crystal 101 may be affixed to block 112 by means of a cement, an epoxy, an adhesive, a Au-Sn eutectic, a solder bond, a braze joint, a polymer-based cement, or the like. One or more edges of nitride crystal 101 may also be ground very accurately. At least one edge of nitride crystal 101 may be co-planar with an edge of block 112. In some embodiments, at least two edges of crystal 101 are co-planar with edges of block 112.

Referring to FIGS. 1e and 1f, a handle substrate 117 having a surface 115 is provided. Handle substrate 117 may comprise a single crystal, polycrystalline or amorphous material. Handle substrate 117 may comprise sapphire, aluminum oxide, mullite, silicon, silicon nitride, germanium, gallium arsenide, silicon carbide, MgAl₂O₄ spinel, zinc oxide, indium phosphide, gallium nitride, indium nitride, gallium aluminum indium nitride, or aluminum nitride. Handle substrate 117 may comprise substantially the same composition as crystal 101. In one specific embodiment, handle substrate 117 comprises crystals that have been merged or tiled together using another method. For example, handle substrate 117 may be formed using at least one of the tiling methods disclosed by Dwilinski et al. [U.S. Patent Application No. 2008/0156254] or the method disclosed in U.S. patent application Ser. No. 12/635645, which is hereby incorporated by reference in its entirety. In a preferred embodiment, handle substrate 117 comprises substantially the same composition as crystal 101 and has a crystallographic orientation within about 10 degrees, within about 5 degrees, within about 2 degrees, or within about 1 degree of that of crystal 101. Handle substrate 117 may comprise a glass. Handle substrate 117 may comprise an oxide of at least one of Si, Ge, Sn, Pb, B, Al, Ga, In, Tl, P, As, Sb, Pb, Li, Na, K, Rb, Cs, Mg, Ca, Sr, Ba, Y, Ti, Zr, Hf, Mn, Zn, or Cd. In one specific embodiment, handle substrate 117 comprises borophosphosilicate glass. Handle substrate 117 may have a thermal expansion coefficient parallel to surface 115 between room temperature and about 700 degrees Celsius that is between about 2.5×10⁻⁶ K⁻¹ and about 7×10⁻⁶ K⁻¹. Handle substrate 117 may have a thermal expansion coefficient parallel to surface 115 between room temperature and about 700 degrees Celsius that is between about 5.5×10⁻⁶ K⁻¹ and about 6.5×10⁻⁶ K⁻¹. Handle substrate 117 may have a softening point, that is, where its viscosity has a value of about 10⁸ Poise, at a temperature between about 500 degrees Celsius and about 1400 degrees Celsius. Handle substrate 117 may have a glass transition temperature between about 600 degrees Celsius and about 1200 degrees Celsius. Handle substrate 117 may have a softening point, that is, where its viscosity has a value of about 10⁸ Poise, at a temperature between about 600 degrees Celsius and about 900 degrees Celsius. Surface 115 may be optically flat, with a deviation from flatness less than 1 micron, less than 0.5 micron, less than 0.2 micron, less than 0.1 micron, or less than 0.05 micron. Surface 115 may be very smooth, with a root-mean-square roughness less than 5 nanometers, less than 2 nanometers, less than 1 nanometer, less than 0.5 nanometer, less than 0.2 nanometer, less than 0.1 nanometer, or less than 0.05 nanometer, measured over an area of at least 10 microns×10 microns.

An adhesion layer 113 may be deposited on surface 115 of handle substrate 117. Adhesion layer 113 may comprise at least one of SiO₂, GeO₂, SiNₓ, AlNₓ, or B, Al, Si, P, Zn, Ga, Si, Ge, Au, Ag, Ni, Ti, Cr, Zn, Cd, In, Sn, Sb, Tl, or Pb, or an oxide, nitride, or oxynitride thereof. Adhesion layer 113 may further comprise hydrogen. The adhesion layer 113 may be deposited by thermal evaporation, electron-beam evaporation, sputtering, chemical vapor deposition, plasma-enhanced chemical vapor deposition, or the like, or by thermal oxidation of a deposited metallic film. The thickness of adhesion layer 113 may between about 1 nanometer and about 10 microns, or between about 10 nanometers and about 1 micron. In some embodiments, an adhesion layer is deposited on surface 105 of nitride crystal 101 or on surface 111 of high quality epitaxial layer 109 (not shown). The adhesion layer(s) may be annealed, for example, to a temperature between about 300 degrees Celsius and about 1000 degrees Celsius. In some embodiments, an adhesion layer is deposited on surface 105 of crystal 101 and annealed prior to forming an implanted/damaged layer by ion implantation. In some embodiments, at least one adhesion layer is chemical-mechanically polished. In a preferred embodiment, the root-mean-square surface roughness of at least one adhesion layer is below about 0.5 nanometer, or below about 0.3 nanometer over a 20×20 μm² area.

Referring again to FIGS. 1e and 1f, surface 105 of nitride crystal 101, surface 111 of high quality epitaxial layer 109, or an adhesion layer placed thereupon, is placed in contact with adhesion layer 113 and/or with the surface 115 of the handle substrate 117 and wafer-bonded. In a preferred embodiment, the wafer bonding operation is performed in a clean room, with less than 10,000, less than 1,000, less than 100, or less than 10 particles per cubic centimeter in the air. Particles may be removed from at least one of the surfaces immediately prior to wafer bonding by spraying, brushing, or rinsing with ionized nitrogen, a CO₂ jet, CO₂ snow, high-resistivity water, an organic solvent, such as methanol, ethanol, isopropanol, acetone, or the like. In some embodiments, surface 105 or surface 109, or the surface of an adhesion layer placed thereupon, and surface 113 or surface 115 are brought into contact while immersed in a liquid. Optionally, at least one of the surfaces is exposed to a plasma to enhance wafer bonding.

The positional and orientational accuracy of the placement of nitride crystal 101 with respect to handle substrate 117 is precisely controlled. In one specific embodiment nitride crystal is placed on handle substrate 117 by a pick and place machine, or robot, or a die attach tool. Nitride crystal 101 may be picked up by a vacuum chuck, translated to the desired position above handle substrate 117 by a stepper-motor-driven x-y stage, re-oriented, if necessary, by a digital-camera-driven rotational drive, and lowered onto the handle substrate. The positional accuracy of placement may be better than 50 microns, better than 30 microns, better than 20 microns, better than 10 microns, or better than 5 microns. The orientational accuracy of placement may be better than 5 degrees, better than 2 degrees, better than 1 degree, better than 0.5 degree, better than 0.2 degree, better than 0.1 degree, better than 0.05 degree, better than 0.02 degree, or better than 0.01 degree. In another specific embodiment, block 112, attached to nitride crystal 101, is placed in a kinematic mount. The kinematic mount establishes orientational accuracy with respect to handle substrate 117 that is better than 1 degree, better than 0.5 degree, better than 0.2 degree, better than 0.1 degree, better than 0.05 degree, better than 0.02 degree, or better than 0.01 degree. Nitride crystal 101, block 112, and the kinematic mount may then be positioned with respect to handle substrate 117 with submicron accuracy using an x-y stage similar to that in a stepper photolithography tool, using stepper motors in conjunction with voice coils. In some embodiments, the azimuthal crystallographic orientations of crystal 101 and handle substrate 117 are equivalent to within about 10 degrees, within about 5 degrees, within about 2 degrees, or within about 1 degree.

Nitride crystal 101 may be pressed against handle substrate 117 with a pressure between about 0.1 megapascals and about 100 megapascals. In some embodiments, van der Waals forces are sufficient to obtain a good wafer bond and no additional applied force is necessary. Nitride crystal 101 and handle substrate 117 may be heated to a temperature between about 30 degrees Celsius and about 950 degrees Celsius, between about 30 degrees Celsius and about 400 degrees Celsius, between about 30 degrees Celsius and about 200 degrees Celsius to strengthen the wafer bond. In some embodiments, heating of nitride crystal 101 and handle substrate 113 is performed while they are mechanically loaded against one another.

In some embodiments, at least the surface region of bonded nitride crystal 101 having implanted/damaged region 103 and handle substrate 117 are heated to a temperature between about 200 degrees Celsius and about 800 degrees Celsius or between about 500 degrees Celsius and about 700 degrees Celsius to cause micro-bubbles, micro-cracks, micro-blisters, or other mechanical flaws within region 103. In one specific embodiment, surface region 105 or 109 is heated by means of optical or infrared radiation through handle substrate 117, and the distal portion of crystal 101, which may be in contact with block 112, may remain less than about 300 degrees Celsius, less than about 200 degrees Celsius, or less than about 100 degrees Celsius. In some embodiments, mechanical energy may be provided instead of or in addition to thermal energy. In some embodiments, an energy source such as a pressurized fluid is directed to a selected region, such as an edge, of bonded nitride crystal 101 to initiate a controlled cleaving action within region 103. After the application of energy, the distal portion of nitride crystal 101 is removed, leaving a proximate portion of nitride crystal 101 bonded to handle substrate 117. In some embodiments, distal portion of nitride crystal 101 remains bonded to block 112. In some embodiments, the newly exposed surface of distal portion of nitride crystal 101 is polished, dry-etched, or chemical-mechanically polished. Care is taken to maintain the surface crystallographic orientation of the newly exposed surface of distal portion of nitride crystal 101 the same as the original orientation of surface 105. In some embodiments, an adhesion layer is deposited on the newly exposed surface of distal portion of crystal 101. In some embodiments, the adhesion layer is chemical-mechanically polished.

Referring to FIG. 1g, in some embodiments, nitride crystal 101 is separated from high quality epitaxial layer 109 and handle substrate 117 by laser irradiation. The release layer 107 may be illuminated through nitride crystal 101 by laser radiation 125 having a wavelength at which the release layer has an optical absorption coefficient greater than 1000 cm⁻¹ and the nitride crystal is substantially transparent, with an optical absorption coefficient less than 50 cm⁻¹. In another set of embodiments, the release layer is illuminated through handle substrate 117 by laser radiation 127 having a wavelength at which the release layer has an optical absorption coefficient greater than 1000 cm⁻¹ and the handle substrate is substantially transparent, with an optical absorption coefficient less than 50 cm⁻¹. Absorption of the laser energy by the release layer 109 occurs on a very short length scale, causing considerable local heating. Without wishing to be bound by theory, we believe that the local heating causes partial or complete decomposition of the release layer and/or a thin portion of the nitride crystal in direct contact with the release layer, forming metal and N₂, which may occur as a thin layer or as micro- or nano-bubbles. The thin layer or micro- or nano-bubbles of N₂ mechanically weakens the interface between the nitride crystal and the high quality epitaxial layer, enabling facile separation of the nitride crystal from the high quality epitaxial layer, which is in turn bonded to the handle substrate. The optimal degree of weakening of the interface, without causing undesired damage to the high quality epitaxial layer or the handle substrate, is achieved by adjusting the die temperature, the laser power, the laser spot size, the laser pulse duration, and/or the number of laser pulses. The laser fluence to effect separation may be between 300 and 900 millijoules per square centimeter or between about 400 mJ/cm² and about 750 mJ/cm². The uniformity of the laser beam may be improved by inclusion of a beam homogenizer in the beam path, and the beam size may be about 4 mm by 4 mm. In some embodiments, the laser beam is scanned or rastered across the release layer rather than being held stationary. Separation may be performed at a temperature above the melting point of the metal produced by decomposition, e.g., above about 30 degrees Celsius in the case of gallium metal.

In some embodiments, multiple release layers and high quality epitaxial layers are present in the wafer-bonded stack. In this case laser illumination is preferably applied through the handle substrate, and the fluence controlled so that substantial decomposition takes place only within the release layer closest to the handle substrate and the remaining release layers and high quality epitaxial layers remain bonded to the nitride crystal after liftoff.

After separation of the high quality epitaxial layer from the nitride crystal, any residual gallium, indium, or other metal or nitride on the newly exposed back surface of the high quality epitaxial layer, on nitride crystal 101, or on another newly-exposed high quality epitaxial layer still bonded to nitride crystal 101 may be removed by treatment with at least one of hydrogen peroxide, an alkali hydroxide, tetramethylammonium hydroxide, an ammonium salt of a rare-earth nitrate, perchloric acid, sulfuric acid, nitric acid, acetic acid, hydrochloric acid, and hydrofluoric acid. The surfaces may be further cleaned or damage removed by dry-etching in at least one of Ar, Cl₂, and BCl₃, by techniques such as chemically-assisted ion beam etching (CAIBE), inductively coupled plasma (ICP) etching, or reactive ion etching (RIE). The surfaces may be further treated by chemical mechanical polishing.

In some embodiments, traces of the release layer may remain after laser liftoff or etching from the edges of the release layer. Residual release layer material may be removed by photoelectrochemical etching, illuminating the back side of the high quality epitaxial layer or the front side of nitride crystal 101 or of the front side of the outermost high quality epitaxial layer still bonded to nitride crystal 101 with radiation at a wavelength at which the release layer has an optical absorption coefficient greater than 1000 cm⁻¹ and the high quality epitaxial layer is substantially transparent, with an optical absorption coefficient less than 50 cm⁻¹.

Referring to FIG. 1h, in another set of embodiments, the high quality epitaxial layer bonded to the handle substrate is separated from the nitride crystal by means of chemical etching of the release layer. In one embodiment, one or more edges of the release layer is treated with at least one of 1,2-diaminoethane, hydrogen peroxide, an alkali hydroxide, tetramethylammonium hydroxide, an ammonium salt of a rare-earth nitrate, perchloric acid, sulfuric acid, nitric acid, acetic acid, hydrochloric acid, and hydrofluoric acid. In one specific embodiment, the edge of the release layer is etched by treatment in a mixture of 200 milliliters of deionized water, 50 grams of diammonium cerium nitrate, Ce(NH₄)₂(NO₃)₆, and 13 milliliters of perchloric acid, HClO₄, at approximately 70 degrees Celsius. At least one edge of the release layer is etched away, mechanically weakening the interface between the nitride base crystal and the high quality epitaxial layer and enabling facile separation of the nitride base crystal from the high quality epitaxial layer, which is in turn bonded to at least one semiconductor device layer. The right degree of weakening of the interface, without causing undesired damage to the high quality epitaxial layer or the semiconductor structure, is achieved by adjusting the temperature and time of the chemical treatment. The time required for lateral etching of the release layer may be reduced by incorporating a pre-formed set of channels in the release layer. In the case that multiple, alternating release layers and high quality epitaxial layers are bonded to nitride crystal 101, transfer may be restricted to the outermost high quality epitaxial layer by utilizing etch channels that penetrate only the outermost high quality epitaxial layer.

In still another set of embodiments, the high quality epitaxial layer bonded to the handle substrate is separated from the nitride crystal by means of photoelectrochemical (PEC) etching of the release layer. For example, an InGaN layer or InGaN/InGaN superlattice may be deposited as the release layer. An electrical contact may be placed on the nitride crystal and the release layer illuminated with above-bandgap radiation, for example, by means of a Xe lamp and a filter to remove light with energy greater than the bandgap of the high quality epitaxial layer and/or the nitride crystal. In one set of embodiments, illustrated schematically in FIG. 1i, the illumination 127 is provided through the handle substrate and the intensity adjusted so that essentially all the light is absorbed by the release layer in closest proximity to the handle substrate. At least one edge of the release layer is exposed to an electrolyte, for example, a stirred, 0.004M HCl solution. The time required for lateral etching of the release layer may be reduced by incorporating a pre-formed set of channels in the release layer. In the case that multiple, alternating release layers and high quality epitaxial layers are bonded to nitride crystal 101, transfer may be restricted to the outermost high quality epitaxial layer even when the etch channels penetrate multiple high quality epitaxial layers by ensuring that the light is fully absorbed by only the outermost release layer. Further details of the PEC etching process are described by Sharma et al., Applied Physics Letters 87, 051107 (2005) and references therein. In one set of embodiments, GaN is deposited as the release layer and lattice-matched AlInN comprises the high quality epitaxial layer, and the wavelength range of the illumination is chosen so that electron-hole pairs are generated in the GaN but not in the AlInN.

In yet another set of embodiments, the high quality epitaxial layer bonded to the handle substrate is separated from the nitride crystal by means of selective oxidation followed by chemical etching of the release layer. For example, at least one release layer comprising AlₓIn_{y}Ga_{1-x-y}N, where 0<x, x+y≦1, 0≦y≦1, or Al_{0.83}In_{0.17}N, lattice matched to GaN, may be selectively oxidized. The selective oxidation may be performed by exposing at least one edge of the Al-containing release layer to a solution comprising nitriloacetic acid (NTA) and potassium hydroxide at a pH of approximately 8 to 11 and an anodic current of approximately 20 μA/cm², to about 0.1 kA/cm², as described by Dorsaz et al., Applied Physics Letters 87, 072102 (2005) and by Altoukhov et al., Applied Physics Letters 95, 191102 (2009) and references cited therein. The oxide layer may then be removed by treatment in a nitric acid solution at approximately 100 degrees Celsius. The time required for lateral etching of the release layer may be reduced by incorporating a pre-formed set of channels in the release layer. In the case that multiple, alternating release layers and high quality epitaxial layers are bonded to nitride crystal 101, transfer may be restricted to the outermost high quality epitaxial layer by utilizing etch channels that penetrate only the outermost high quality epitaxial layer.

Referring to FIG. 1j and 1k, the wafer bonding process is repeated. A second nitride crystal, or the distal portion of the first nitride crystal, is wafer bonded in close proximity to the first nitride crystal or to the proximate portion of first nitride crystal. The second nitride crystal may have an ion-implanted, damaged region or at least one release layer and at least one high quality epitaxial layer, similar to the first nitride crystal. The second nitride crystal or the outer most high quality epitaxial layer on the second nitride crystal has a surface 135 whose crystallographic orientation is essentially identical to that of surface 105 of the nitride crystals 101 or to that of surface 111 of the first high quality epitaxial layer. In some embodiments, accurate equality between the surface orientation of the first and second nitride crystals is achieved by growing each crystal to an accurately flat on-axis orientation, for example, (0 0 0 1) Ga-polar, (0 0 0 −1) N-polar, {1 0-1 0} non-polar, or {1 0-1±1} semi-polar. If the first and/or second nitride crystals are polished, dry-etched, or chemical-mechanically polished, care is taken so as not to significantly alter the surface orientation of either. In some embodiments, accurate equality between the surface orientation of the first and second nitride crystals is achieved by removing a uniform, thin proximate portion of the first nitride crystal to form the second nitride crystal. If the distal portion of the first nitride crystal, used also as the second nitride crystal, is polished, dry-etched, or chemical-mechanically polished, care is taken so as not to significantly alter the surface orientation. In other embodiments, accurate equality between the surface orientation of the first and second nitride crystals is achieved by removing a uniform, thin high quality epitaxial layer from the first nitride crystal to form the second nitride crystal. If the distal portion of the first nitride crystal, used also as the second nitride crystal, is polished, dry-etched, or chemical-mechanically polished, care is taken so as not to significantly alter the surface orientation. For example, the crystallographic orientations of first surfaces 105 or 111 and 135, respectively, of the outermost surface or high quality epitaxial layers on the first and second nitride crystals may be identical to less than 0.5 degree, less than 0.2 degree, less than 0.1 degree, less than 0.05 degree, less than 0.02 degree, or less than 0.01 degree. In still other embodiments, accurate equality between the surface orientation of the first and second nitride crystals is achieved by very careful crystallographic orientation and grinding and/or polishing, for example, using a high-precision goniometer. After wafer bonding, a distal portion of the second nitride crystal may be removed. Gap 145 between the edges of two or more adjacent nitride crystals or proximate portions thereof may be less than 1 millimeter, less than 100 microns, less than 50 microns, less than 20 microns, less than 10 microns, less than 5 microns, less than 2 microns, or less than 1 micron. The wafer bonding process may be repeated more than two, more than 4, more than 8, more than 16, more than 32, or more than 64 times.

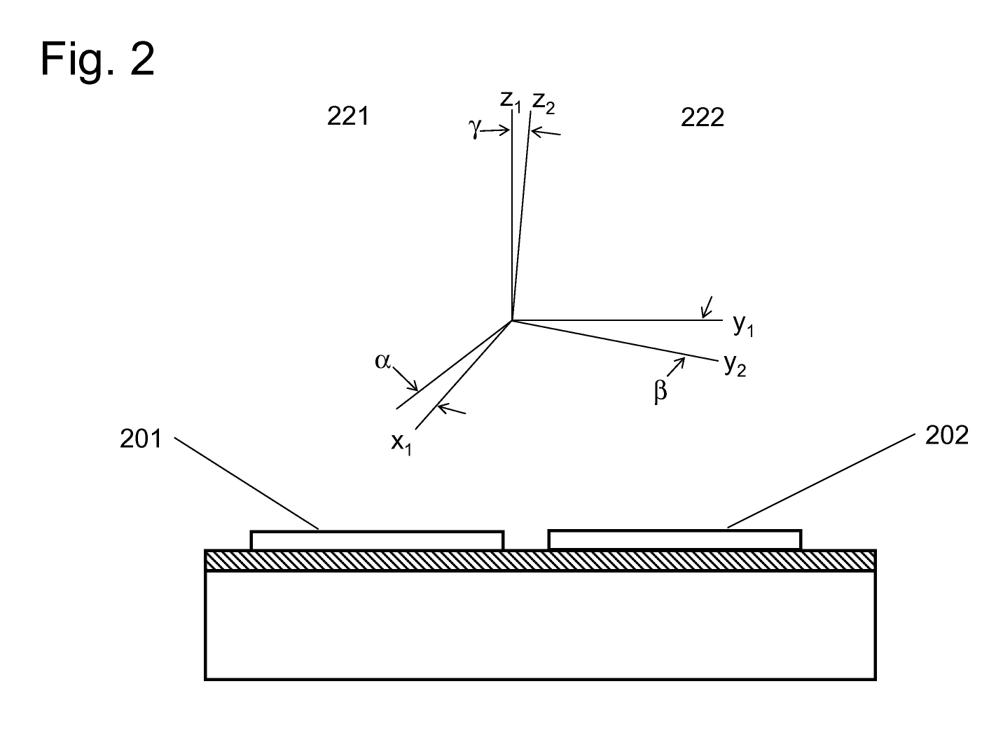

The placement of the second nitride crystal is performed in such as way that the crystallographic orientations between the from the first nitride crystal and the second nitride crystal, or the high quality epitaxial layers thereupon, are very nearly identical. Referring to FIG. 2, coordinate system 221 (x₁ y₁ z₁) represents the crystallographic orientation of the high quality epitaxial layer from the first nitride crystal 201, where z₁ is the negative surface normal of the nominal orientation of surface 111 (cf. FIG. 1) and x₁ and y₁ are vectors that are orthogonal to z₁. For example, if surface 111 has a (0 0 0 1) orientation, then z₁ is a unit vector along [0 0 0 −1], and x₁ and y₁ may be chosen to be along [1 0-1 0] and [1-2 1 0], respectively. If surface 111 has a (1 0-1 0) orientation, then z₁ is a unit vector along [−1 0 1 0] and x₁ and y₁ may be chosen to be along [1-2 1 0] and [0 0 0 1], respectively. Similarly, coordinate system 222 (x₂ y₂ z₂) represents the crystallographic orientation of the high quality epitaxial layer from the second nitride crystal 202, where z₂ is the negative surface normal of the nominal orientation of surface 105 (cf. FIG. 1) and x₂ and y₂ are vectors that are orthogonal to z₂, where the same convention is used for the crystallographic directions corresponding to (x₂ y₂ z₂) as for (x₁ y₁ z₁). The crystallographic misorientation between the first nitride crystal and the second nitride crystal may be specified by the three angles α, β, and γ, where αis the angle between x₁ and x₂, β is the angle between y₁ and y₂, and γ is the angle between z₁ and z₂. Because the surface orientations of the first and second nitride crystals are nearly identical, the polar misorientation angle γ is very small, for example, less than 0.5 degree, less than 0.2 degree, less than 0.1 degree, less than 0.05 degree, less than 0.02 degree, or less than 0.01 degree. Because of the precise control in the orientation of the nitride crystal during placement, the misorientation angles α and β are also very small, for example, less than 1 degree, less than 0.5 degree, less than 0.2 degree, less than 0.1 degree, less than 0.05 degree, less than 0.02 degree, or less than 0.01 degree. Typically, γ will be less than or equal to α and β. The crystallographic misorientation between additional, adjacent nitride crystals is similarly very small.

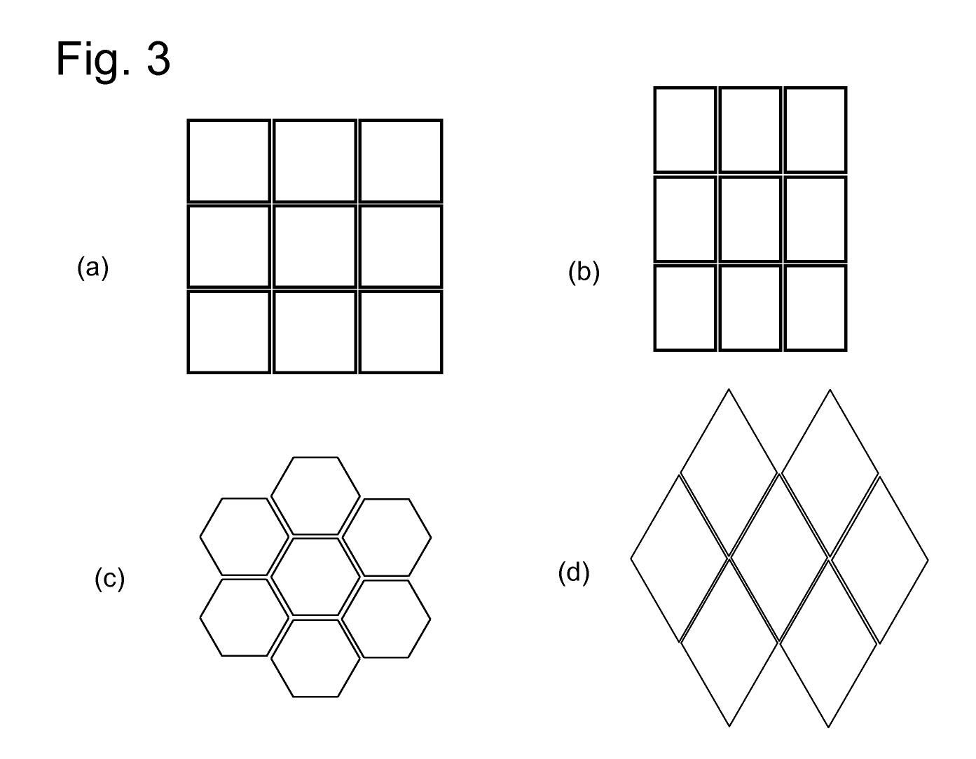

Referring to FIG. 3, after placing and wafer bonding a number of similarly-sized and similarly-shaped high quality epitaxial layers from one or more nitride crystals, a tiled arrangement of high quality epitaxial layers may be formed, with each adjacent pair on the handle substrate being accurately aligned crystallographically with its neighbor(s). The tiling pattern may be (a) square, (b) rectangular, (c) hexagonal, or (d) rhombal. Other arrangements are also possible. The gaps between the edges of two or more adjacent high quality epitaxial layers may be less than 1 millimeter, less than 100 microns, less than 50 microns, less than 20 microns, less than 10 microns, less than 5 microns, less than 2 microns, or less than 1 micron.

In some embodiments, a similar set of nitride crystals or high quality epitaxial layers is wafer-bonded to the back surface of the handle substrate by an analogous procedure to that used to form the tile pattern of nitride crystals or high quality epitaxial layers on the front surface of the handle substrate. In a preferred embodiment, the tile pattern on the back surface of the handle substrate is a mirror image of the tile pattern on the front surface of the handle substrate, with the front and back tile patterns in registry.

In one set of embodiments, the at least two nitride crystals or high quality epitaxial layers on the handle substrate are used as substrate for fabrication of one or more devices. The two or more tiled high quality epitaxial layers or crystals bonded to the handle substrate may be prepared for lateral growth for epitaxial growth and/or for fusion of the tiled crystals into a single larger crystal. The lateral crystal growth may be achieved by techniques such as metalorganic chemical vapor deposition (MOCVD), hydride vapor phase epitaxy (HVPE), ammonothermal crystal growth, or crystal growth from a flux.

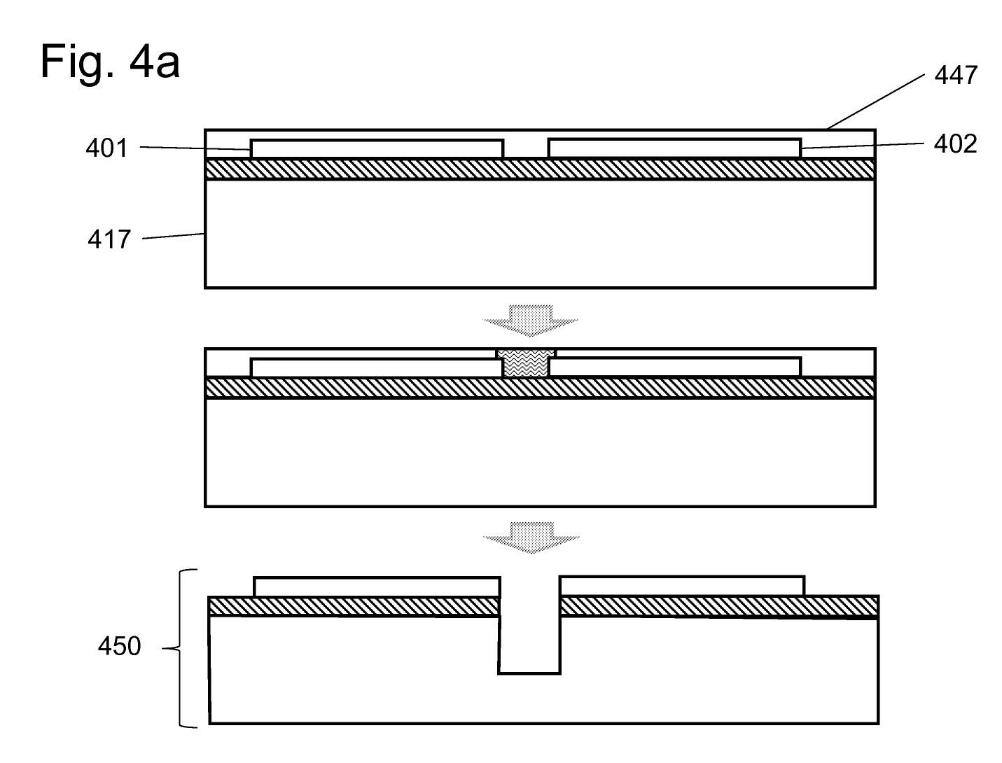

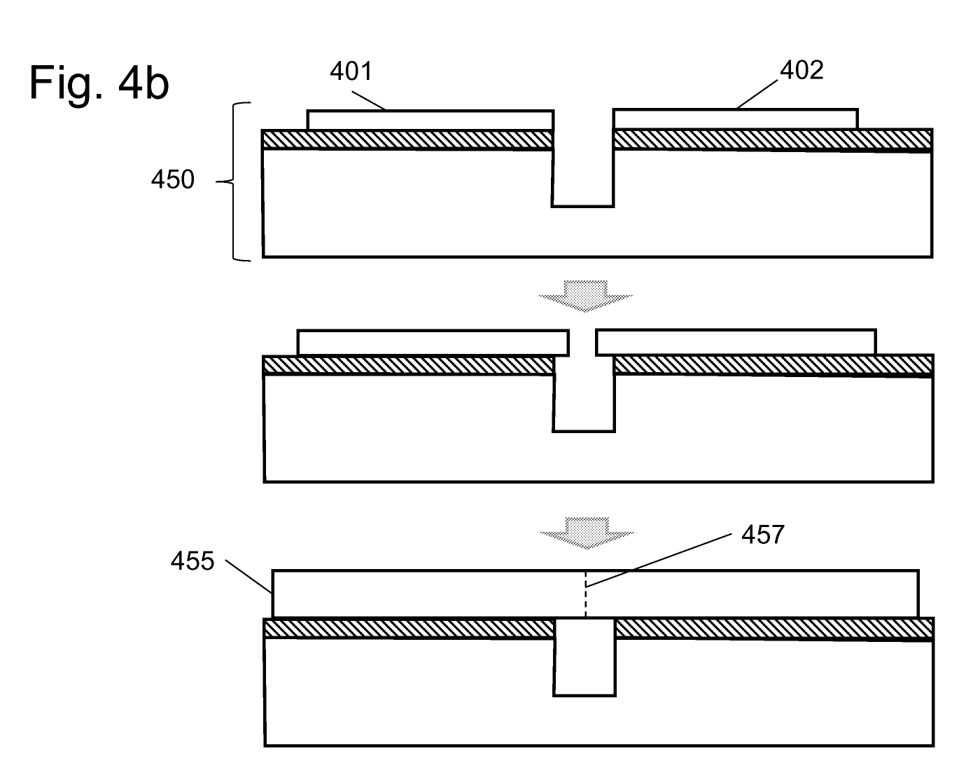

In some embodiments, the handle substrate is suitable for exposure to the epitaxial growth environment without further treatment. In some embodiments, growth may proceed more smoothly, with fewer stresses, if the gaps between adjacent nitride crystals are undercut. Referring to FIG. 4a, a photoresist 447 may be spun onto the wafer bonded, tiled substrate comprising handle substrate 417, first nitride crystal 401, and second nitride crystal 402. Photoresist 447 may be exposed through a mask, etched, and the exposed channel etched by dry etching, and the photoresist removed to form patterned nitride/handle substrate 450. Referring to FIG. 4b, patterned nitride/handle substrate 450 may be used as a substrate for epitaxial nitride growth by MOCVD, HVPE, ammonothermal growth, or flux growth. Growth is performed as known in the art, and the at least two nitride crystals 401 and 402 grow both laterally and vertically to form a merged nitride crystal 455. Because of the very low crystallographic misorientation between nitride crystals 401 and 402, the coalescence front 457 may have a modest concentration of dislocations but a classical low angle grain boundary or tilt boundary may be difficult to detect.

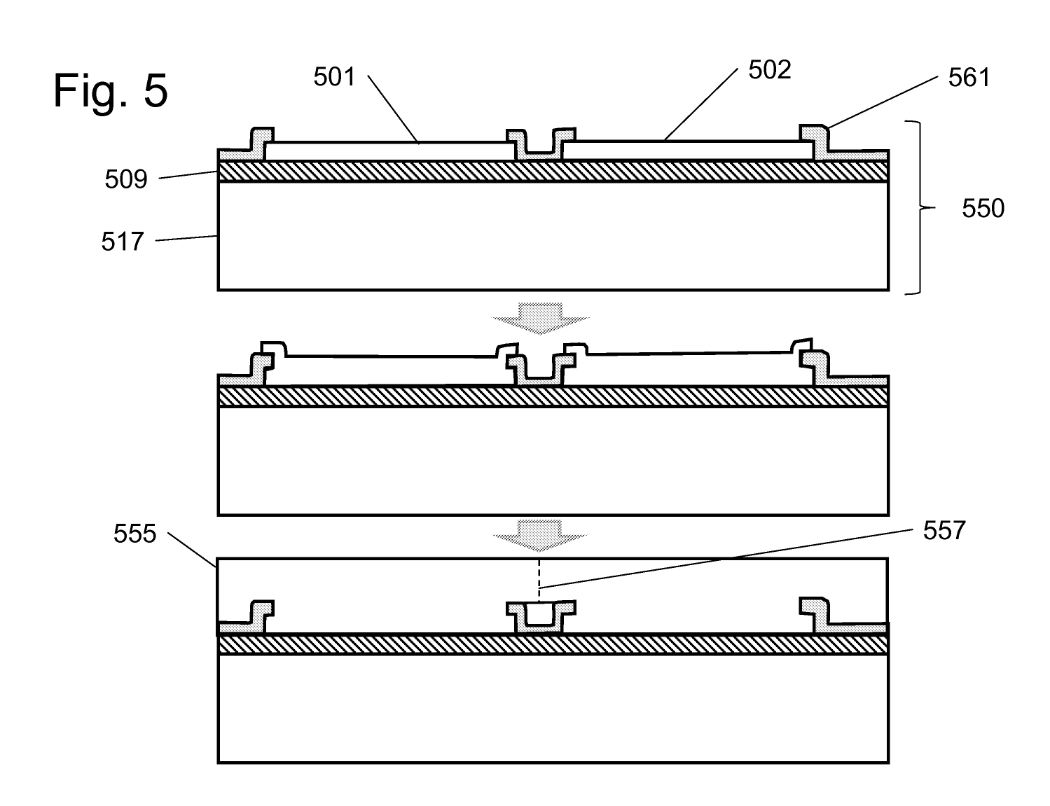

In some embodiments, the handle substrate and/or the adhesion layer may not be suitable for exposure to the epitaxial growth environment without further treatment. Exposed portions of the handle substrate may be coated with a suitable inert material. Referring to FIG. 5, nitride crystals 501 and 502 may be masked, for example, by a shadow mask or by photolithography with a photoresist, and the regions between the masked areas on the handle substrate 517 and/or adhesion layer 509 coated with inert coating 561. Inert coating 561 may comprise at least one of Ag, Au, Pt, Pd, Rh, Ru, Ir, SiO₂, SiNₓ, or AN. Inert coating 561 may further comprise an adhesion layer (not shown) in contact with the surface of handle substrate 517 and/or adhesion layer 509 comprising, for example, at least one of Ti, V, Cr, Al, or Ni. Inert coating 561 may be deposited by sputtering, thermal evaporation, electron beam evaporation, chemical vapor deposition, plasma enhanced chemical vapor deposition, or the like. Masked nitride/handle substrate 550 may be used as a substrate for epitaxial nitride growth by MOCVD, HVPE, ammonothermal growth, or flux growth. Flux growth may be performed, for example, using liquid Ga under a nitrogen pressure of 1-3 GPa, using an alloy comprising Ga and at least one alkali metal under a pressure of a nitrogen-containing gas at a pressure of 10-200 MPa, or using one or more halide, nitride, or amide salts under a pressure of a nitrogen-containing gas at a pressure of 0.1-200 MPa. Growth is performed as known in the art, and the at least two nitride crystals 501 and 502 grow both laterally and vertically to form a merged nitride crystal 555. Because of the very low crystallographic misorientation between nitride crystals 501 and 502, the coalescence front 557 may have a modest concentration of dislocations but a classical low angle grain boundary or tilt boundary may be difficult to detect.

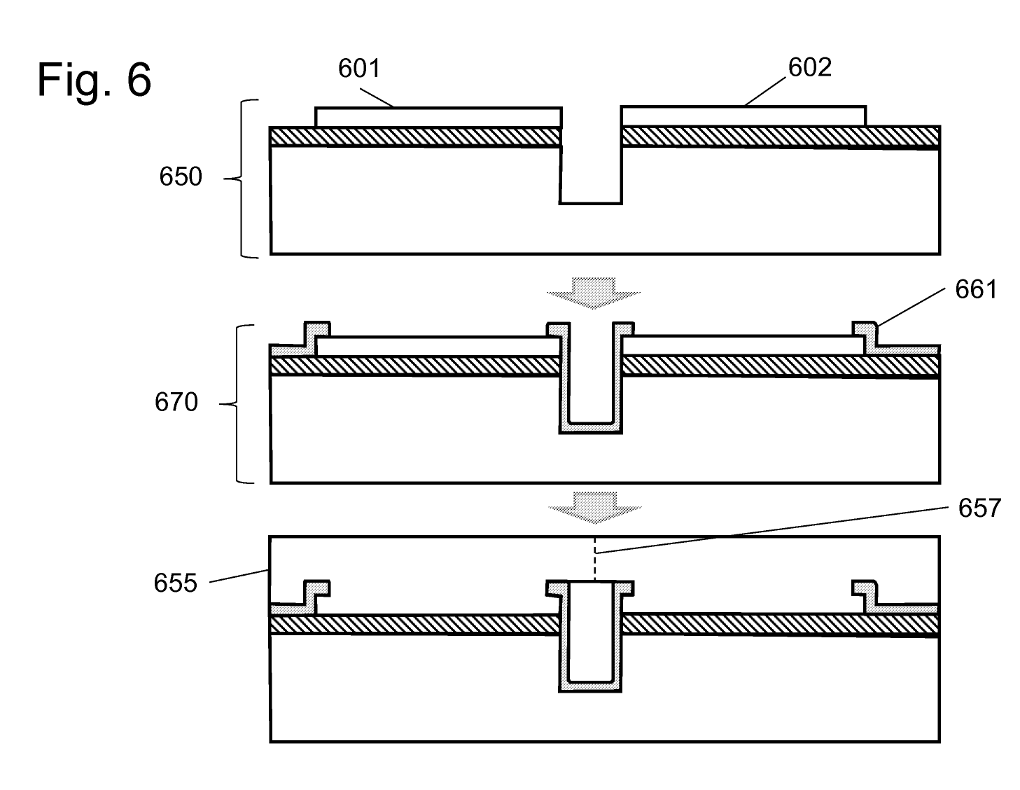

The etching/patterning and masking steps may be combined. Referring to FIG. 6, nitride crystals 601 and 602 with an etched gap between them may be masked, for example, by a shadow mask or by photolithography with a photoresist, and the regions between the masked areas on handle substrate 617 and/or adhesion layer 609 coated with inert coating 661. Masked/patterned/etched nitride/handle substrate 670 may be used as a substrate for epitaxial nitride growth by MOCVD, HVPE, ammonothermal growth, or flux growth. Growth is performed as known in the art, and the at least two nitride crystals 601 and 602 grow both laterally and vertically to form a merged nitride crystal 655. Because of the very low crystallographic misorientation between nitride crystals 601 and 602, the coalescence front 657 may have a modest concentration of dislocations but a classical low angle grain boundary or tilt boundary may be difficult to detect.

The merged nitride crystal may be grown to a thickness greater than 5 microns, greater than 50 microns, greater than 0.5 millimeters, or greater than 5 millimeters. After cooling and removal from the reactor, the merged nitride crystal may be separated from the handle substrate. The inert coating, if present, may be removed from at least a portion of the edge of the handle substrate by scribing, abrasion, or the like. The handle substrate may be dissolved or etched away, for example, by placing in contact with an acid, a base, or a molten flux, preferably in a way that produces negligible etching or other damage to the merged nitride crystal. For example, a glass, silicon, or germanium substrate may be etched away without damaging the merged nitride crystal by treatment in a solution comprising HF and/or H₂SiF₆. Alternatively, a a glass or zinc oxide substrate may be etched away without damaging the merged nitride crystal by treatment in a solution comprising NaOH, KOH, or NH₄OH. A gallium arsenide or zinc oxide substrate may be etched away without damaging the merged nitride crystal by treatment in a solution comprising aqua regia or one or more of HCl, HNO₃, HF, H₂SO₄, and H₃PO₄. A sapphire or alumina substrate may be etched away without damaging the merged nitride crystal by treatment in molten KBF₄. After removal of the handle substrate, one or more surface of the merged nitride crystal may be lapped, polished, and/or chemical-mechanically polished. The merged nitride crystal may be sliced (sawed, polished, and/or chemical-mechanically polished) into one or more wafers.

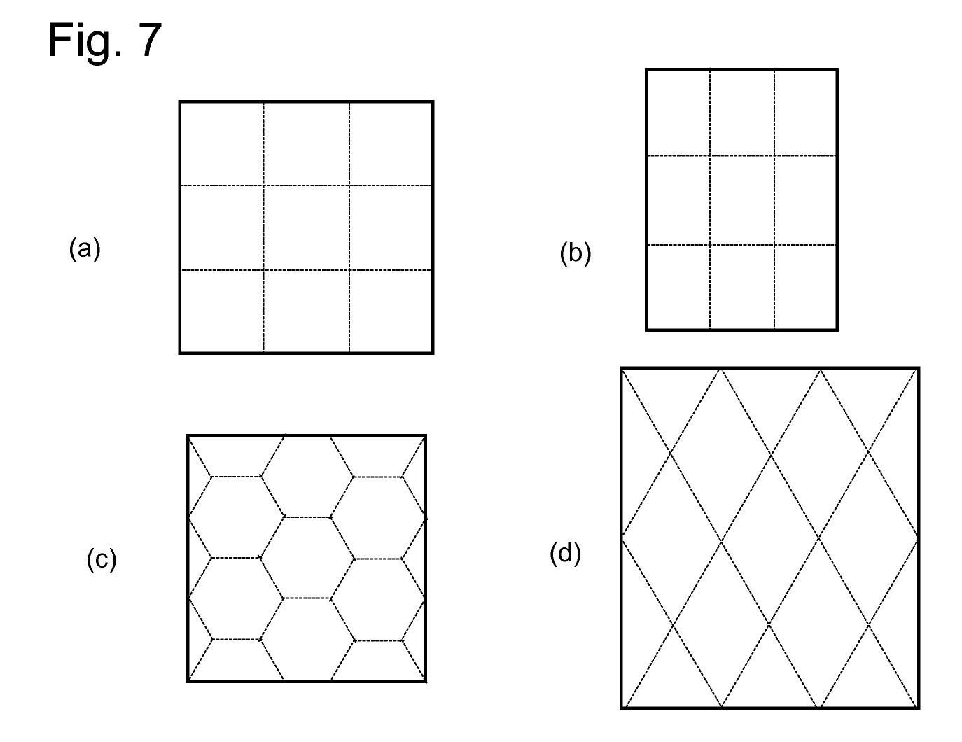

Referring to FIG. 7, the merged nitride crystal comprises two or more domains separated by one or more lines of dislocations. Depending on the geometry of the original nitride crystals, the pattern of domains may be (a) square, (b) rectangular, (c) hexagonal, or (d) rhombal. Other patterns are also possible. The polar misorientation angle y between adjacent domains may be less than 0.5 degree, less than 0.2 degree, less than 0.1 degree, less than 0.05 degree, less than 0.02 degree, or less than 0.01 degree. The misorientation angles α and β between adjacent domains may be less than 1 degree, less than 0.5 degree, less than 0.2 degree, less than 0.1 degree, less than 0.05 degree, less than 0.02 degree, or less than 0.01 degree. Typically, γ will be less than or equal to α and β. The density of dislocations along the lines between adjacent domains may be less than 5×10⁵ cm⁻¹, less than 2×10⁵ cm⁻¹, less than 1×10⁵ cm⁻¹, less than 5×10⁴ cm⁻¹, less than 2×10⁴ cm⁻¹, less than 1×10³ cm⁻¹, less than 5×10³ cm⁻¹, less than 2×10³ cm⁻¹, or less than 1×10³ cm⁻¹. The density of dislocations along the lines between adjacent domains may be greater than 50 cm⁻¹, greater than 100 cm⁻¹, greater than 200 cm⁻¹, greater than 500 cm⁻¹, greater than 1000 cm⁻¹, greater than 2000 cm⁻¹, or greater than than 5000 cm⁻¹.

Within individual domains, the merged nitride crystal may have a surface dislocation density less than about 10⁷ cm⁻², less than about 10⁶ cm⁻², less than about 10⁵ cm⁻², less than about 10⁴ cm⁻², less than about 10³ cm⁻², or less than about 10² cm⁻². The domains may have a stacking-fault concentration below 10³ cm⁻¹, below 10² cm⁻¹, below 10 cm⁻¹ or below 1 cm⁻¹. The merged nitride crystal may have a symmetric x-ray rocking curve full width at half maximum (FWHM) less than about 300 arc sec, less than about 200 arc sec, less than about 100 arc sec, less than about 50 arc sec, less than about 35 arc sec, less than about 25 arc sec, or less than about 15 arc sec. The merged nitride crystal may have a thickness between about 100 microns and about 100 millimeters, or between about 1 millimeter and about 10 millimeters. The merged nitride crystal may have a diameter of at least about 5 millimeters, at least about 10 millimeters, at least about 15 millimeters, at least about 20 millimeters, at least about 25 millimeters, at least about 35 millimeters, at least about 50 millimeters, at least about 75 millimeters, at least about 100 millimeters, at least about 150 millimeters, at least about 200 millimeters, or at least about 400 millimeters. The surface of the merged nitride crystal may have a crystallographic orientation within 5 degrees, within 2 degrees, within 1 degree, within 0.5 degree, within 0.2 degree, within 0.1 degree, within 0.05 degree, within 0.02 degree, or within 0.01 degree of (0 0 0 1) Ga-polar, (0 0 0 −1) N-polar, {1 0-1 0} non-polar, or {1 1-2 0} non-polar a-plane. The surface of the merged nitride crystal may have a (h k i l) semi-polar orientation, where i=−(h+k) and l and at least one of h and k are nonzero. In a specific embodiment, the crystallographic orientation of the merged nitride crystal is within 5 degrees, within 2 degrees, within 1 degree, within 0.5 degree, within 0.2 degree, within 0.1 degree, within 0.05 degree, within 0.02 degree, or within 0.01 degree of {1 0-1±1}, {1 0-1±2}, {1 0-1±3}, {1 1-2±2}, {2 0-2±1}, {2 1-3±1}, or {3 0-3±4}. The merged nitride crystal has a minimum lateral dimension of at least four millimeters. In some embodiments, the merged nitride crystal has a minimum lateral dimension of at least one centimeter, at least two centimeters, at least three centimeters, at least four centimeters, at least five centimeters, at least six centimeters, at least eight centimeters, at least ten centimeters, or at least twenty centimeters.

In some embodiments, the merged nitride crystal is used as a substrate for epitaxy. The merged nitride crystal may be sawed, lapped, polished, dry etched, and/or chemical-mechanically polished by methods that are known in the art. One or more edges of the merged nitride crystal may be ground. The merged nitride crystal, or a wafer formed therefrom, may be placed in a suitable reactor and an epitaxial layer grown by MOCVD, MBE, HVPE, or the like. In a preferred embodiment, the epitaxial layer comprises GaN or AlₓIn_{y}Ga(_{1-x-y})N, where 0≦x, y≦1. The morphology of the epitaxial layer is uniform from one domain to another over the surface because the surface orientation is almost identical.

In some embodiments, the merged nitride crystal is used as a substrate for further tiling. For example, referring to FIGS. 11-1k, the nitride crystal 101 may be chosen to be a merged nitride crystal. The tiling, coalescence, and re-tiling operation may be iterated more than twice, more than 4 times, more than 8 times, or more than 16 times. In this way, by successive tiling operations, a merged nitride crystal with excellent crystalline quality and very large diameter may be fabricated.

The merged nitride crystal crystal, or a wafer sliced and polished from the merged nitride crystal crystal, may be used as a substrate for fabrication into optoelectronic and electronic devices such as at least one of a light emitting diode, a laser diode, a photodetector, an avalanche photodiode, a transistor, a rectifier, and a thyristor; one of a transistor, a rectifier, a Schottky rectifier, a thyristor, a p-i-n diode, a metal-semiconductor-metal diode, high-electron mobility transistor, a metal semiconductor field effect transistor, a metal oxide field effect transistor, a power metal oxide semiconductor field effect transistor, a power metal insulator semiconductor field effect transistor, a bipolar junction transistor, a metal insulator field effect transistor, a heterojunction bipolar transistor, a power insulated gate bipolar transistor, a power vertical junction field effect transistor, a cascode switch, an inner sub-band emitter, a quantum well infrared photodetector, a quantum dot infrared photodetector, a solar cell, and a diode for photoelectrochemical water splitting and hydrogen generation. In some embodiments, the positions of the devices with respect to the domain structure in the merged nitride crystal are chosen so that the active regions of individual devices lie within a single domain of the merged nitride crystal.

In other embodiments, the merged nitride crystal crystal, or a wafer sliced and polished from the merged nitride crystal crystal, is used as a seed crystal for bulk crystal growth. In one specific embodiment, the tiled crystal, or a wafer sliced and polished from the merged nitride crystal crystal, is used as a seed crystal for ammonothermal crystal growth. In another embodiment, the tiled crystal, or a wafer sliced and polished from the merged nitride crystal crystal, is used as a seed crystal for HVPE crystal growth.

In still other embodiments, the at least two nitride crystals or high quality epitaxial layers on the handle substrate, non-merged, are used as a substrate for fabrication into optoelectronic and electronic devices such as at least one of a light emitting diode, a laser diode, a photodetector, an avalanche photodiode, a transistor, a rectifier, and a thyristor; one of a transistor, a rectifier, a Schottky rectifier, a thyristor, a p-i-n diode, a metal-semiconductor-metal diode, high-electron mobility transistor, a metal semiconductor field effect transistor, a metal oxide field effect transistor, a power metal oxide semiconductor field effect transistor, a power metal insulator semiconductor field effect transistor, a bipolar junction transistor, a metal insulator field effect transistor, a heterojunction bipolar transistor, a power insulated gate bipolar transistor, a power vertical junction field effect transistor, a cascode switch, an inner sub-band emitter, a quantum well infrared photodetector, a quantum dot infrared photodetector, a solar cell, and a diode for photoelectrochemical water splitting and hydrogen generation. The at least one device may flip-chip mounted onto a carrier and the handle substrate removed.

While the above is a full description of the specific embodiments, various modifications, alternative constructions and equivalents may be used. Therefore, the above description and illustrations should not be taken as limiting the scope of the present invention which is defined by the appended claims.

What is claimed is:

1. A method for growth of a large-area crystal, the method comprising:
providing at least two crystals having a dislocation density below about 10⁷ cm⁻² providing a handle substrate;
performing wafer bonding of the at least two crystals to the handle substrate; and
growing the at least two crystals to cause a coalescence into a merged crystal;
wherein the polar misorientation angle γ between the first crystal and the second crystal is less than 0.5 degree and azimuthal misorientation angles α and β are less than 1 degree.

2. The method of claim 1, wherein the at least two crystals have a hexagonal crystal structure.

3. The method of claim 1, wherein the at least two crystals have a cubic crystal structure.

4. The method of claim 3, wherein the at least two crystals are selected from among cubic BN, BP, BAs, AlP, AlAs, AlSb, β-SiC, GaP, GaAs, GaSb, InP, InAs, ZnS, ZnSe, CdS, CdSe, CdTe, CdZeTe, and HgCdTe.

5. The method of claim 2, wherein the at least two crystals are selected from among ZnO, ZnS, AgI, CdS, CdSe, 2H-SiC, 4H-SiC, and 6H-SiC.

6. The method of claim 1, wherein the at least two crystals comprise regions having a concentration of threading dislocations higher than about 10⁶ cm⁻² separated by regions having a concentration of threading dislocations lower than about 10⁶ cm⁻².

7. The method of claim 2 wherein the at least two nitride crystals comprise AlₓIn_{y}Ga_{(1-x-y)}N, where 0≦x, y, x+y≦1.

8. The method of claim 1 wherein the at least two crystals have a dislocation density below about 10⁶ cm⁻².

9. The method of claim 1 wherein the at least two crystals have a dislocation density below about 10⁴ cm⁻².

10. The method of claim 1 wherein at least one of the two crystals has an ion-implanted/damaged region.

11. The method of claim 2, wherein the surfaces of the at least two crystals being wafer-bonded to the handle substrate have a crystallographic orientation within about one degree of (0 0 0 1), (0 0 0 −1), {1 0-1 0}, {1 0-1±1}, {2 0-2 1}, and {1 1-2 2}.

12. The method of claim 1 wherein the handle substrate is selected from among sapphire, aluminum oxide, mullite, silicon, silicon nitride, germanium, silicon germanium, diamond, gallium arsenide, silicon carbide, MgAl₂O₄ spinel, zinc oxide, indium phosphide, gallium nitride, indium nitride, gallium aluminum indium nitride, and aluminum nitride.

13. The method of claim 1 wherein the handle substrate is a glass and comprises an oxide of at least one of materials including Si, Ge, Sn, Pb, B, Al, Ga, In, Tl, P, As, Sb, Pb, Li, Na, K, Rb, Cs, Mg, Ca, Sr, Ba, Y, Ti, Zr, Hf, Mn, Zn, and Cd.

14. The method of claim 1, wherein at least one of the handle substrate and the crystal further comprises an adhesion layer, wherein the adhesion layer comprises at least one of SiO₂, GeO₂, SiNₓ, AlNₓ, B, Al, Si, P, Zn, Ga, Ge, Au, Ni, Ti, Cr, Cd, In, Sn, Sb, Tl, or Pb, or an oxide, nitride, or oxynitride thereof.

15. The method of claim 1, wherein the handle substrate has substantially the same composition as the at least two crystals.

16. The method of claim 1, wherein at least one of the crystals comprises a merged crystal.

17. The method of claim 1, wherein the at least two crystals are placed on the handle substrate by means of a pick and place machine, a robot, or a die attach tool.

18. The method of claim 1 further comprising utilizing the merged crystal as a substrate for a semiconductor structure.

19. The method of claim 17 further comprising arranging the semiconductor structure so that the active region of the semiconductor structure lies within a single domain of the merged crystal.

20. The method of claim 1 including the further step of utilizing the merged crystal as a seed crystal for bulk crystal growth.
